(19) United States
(12) Patent Application Publication
(10) Pub. No.: US 2026/0026118 A1
(43) Pub. Date: Jan. 22, 2026

(54) IMAGE SENSOR

(71) Applicant: Samsung Electronics Co., Ltd., Suwon-si (KR)

(72) Inventors: Sol YOON, Suwon-si (KR); Yongjun KIM, Suwon-si (KR); Seungsik KIM, Suwon-si (KR); Kwansik CHO, Suwon-si (KR)

(73) Assignee: Samsung Electronics Co., Ltd., Suwon-si (KR)

(21) Appl. No.: 19/024,322

(22) Filed: Jan. 16, 2025

(30) Foreign Application Priority Data
Jul. 22, 2024 (KR) 10-2024-0096443

(51) Int. Cl. H10F 39/00; H04N 25/532

(52) U.S. Cl. CPC H10F 39/8037; H04N 25/532; H10F 39/802; H10F 39/811

(57) ABSTRACT

An image sensor includes a substrate and a plurality of pixel regions. At least one of the plurality of pixel regions includes a photoelectric conversion portion in the substrate and a pixel circuit adjacent to the first surface of the substrate. The pixel circuit includes a plurality of transistors. The plurality of transistors includes a first transistor including a first gate electrode and a second transistor including a second gate electrode. The second gate electrode has a structure, a shape, or a depth different from that of the first gate electrode. The plurality of transistors has a buried structure in which the first gate electrode or the second gate electrode is buried inside the substrate.

### CROSS-REFERENCE TO RELATED APPLICATION

This application claims priority to and the benefit of Korean Patent Application No. 10-2024-0096443 filed in the Korean Intellectual Property Office on Jul. 22, 2024, the entire contents of which are incorporated herein by reference.

### BACKGROUND

### (a) Field

At least some inventive concepts relate to an image sensor, for example to an image sensor having an enhanced structure.

### (b) Description of the Related Art

An image sensor may be understood as a semiconductor device that is configured to convert optical images into electrical signals. Image sensors may be classified as, for example, charge coupled device (CCD) type image sensors based on silicon semiconductors and complementary metal oxide semiconductor (CMOS) type image sensors (CIS).

Among these classifications, the CMOS type image sensor may be driven by a simple method and a signal processing circuit may be integrated on a single chip in the CMOS type image sensor. Accordingly, the CMOS type image sensor may be downsized and have relatively low power consumption, and, accordingly, may be applied to products with a limited battery capacity. With the advancement of the electronics industry, various studies are continuing to improve the performance of the CMOS type image sensors.

### SUMMARY

Inventive concepts relate to an image sensor capable of enhancing efficiency and performance.

An image sensor according to some example embodiments may include a substrate including a first surface and a second surface opposite each other; and a plurality of pixel regions. At least one of the plurality of pixel regions includes a photoelectric conversion portion in the substrate and a pixel circuit adjacent to the first surface of the substrate. The pixel circuit includes a plurality of transistors, wherein the plurality of transistors includes a first transistor and a second transistor, the first transistor including a first gate electrode and the second transistor including a second gate electrode, wherein the second gate electrode has a structure, a shape, or a depth that is different from a structure, a shape, or a depth of the first gate electrode, and wherein the plurality of transistors has a buried structure wherein at least one of first gate electrode or the second gate electrode is at least partially buried inside the substrate.

An image sensor according to some example embodiments may include a substrate including a first surface and a second surface opposite each other; and a plurality of pixel regions. At least one of the plurality of pixel regions includes a photoelectric conversion portion in the substrate and a pixel circuit adjacent to the first surface of the substrate. The pixel circuit includes a plurality of transistors, wherein the plurality of transistors includes a first transistor and a second transistor, the first transistor including a first gate electrode and the second transistor including a second gate electrode, wherein the first gate electrode is a vertical transfer gate electrode, wherein the second gate electrode has a structure, a shape, or a depth different from a structure, a shape, or a depth of the first gate electrode, wherein at least one of the plurality of pixel regions includes a plurality of sub-pixel regions, each of the pixel regions includes the first transistor and the second transistor, or at least one of the plurality of pixel regions includes at least one first transistor and a plurality of second transistors, and wherein the plurality of transistors has a buried structure in which the at least one of the first gate electrode or the second gate electrode is at least partially buried inside the substrate.

An image sensor according to some example embodiments may include a substrate including a first surface and a second surface opposite each other; a plurality of pixel regions; and an isolation portion disposed to correspond to a boundary of the plurality of pixel regions. At least one of the plurality of pixel regions includes a photoelectric conversion portion in the substrate and a pixel circuit adjacent to the first surface of the substrate. The pixel circuit includes a transistor, the transistor including a gate electrode and an insulation layer, wherein the gate electrode is at least partially inside the substrate, and wherein the insulation layer is on a first surface of the gate electrode and at a side of the first surface of the substrate, and wherein at least a partial portion of the insulation layer is inside the substrate.

According to some example embodiments, a plurality of transistors may have a buried structure and the plurality of transistors that perform various roles may be easily implemented. For example, when a large number of transistors and/or various circuit elements such as a memory device or the like are included for a specific operation (e.g., a global shutter operation), the plurality of transistors may be easily implemented. By forming an insulation layer on a gate electrode in the transistor, a gate induced drain leakage current may be reduced. Since a connection wiring that connects the transistor and/or a doping region may have a buried structure, a leakage current and parasitic capacitance may be reduced, a number of first contact vias may be reduced, and a wiring may be freely disposed. Accordingly, performance and efficiency of an image sensor may be enhanced.

### BRIEF DESCRIPTION OF THE DRAWINGS

FIG. 1 is a block diagram that schematically illustrates an example of an image sensor.

FIG. 2 is a partial cross-sectional view that illustrates an image sensor according to some example embodiments.

FIG. 3 is an enlarged cross-sectional view that illustrates a portion A in FIG. 2.

FIG. 4 is a plan view that schematically illustrates a substrate of the image sensor illustrated in FIG. 2.

FIG. 5 is a circuit diagram of a pixel array that is included in the image sensor illustrated in FIG. 2.

FIG. 6 is a rear perspective view that conceptually illustrates a reset transistor illustrated in FIG. 4 and first contact vias connected to the reset transistor.

FIG. 7 is a rear perspective view that conceptually illustrates a first driving transistor illustrated in FIG. 4 and first contact vias connected to the first driving transistor.

FIG. 8 to FIG. 16 are cross-sectional views that schematically illustrate a manufacturing method of an image sensor according to some example embodiments.

FIG. 17 is a partial cross-sectional view that illustrates an image sensor according to some example embodiments.

FIG. 18 is an enlarged cross-sectional view that illustrates a portion E in FIG. 17.

FIG. 19 is a circuit diagram of a pixel array that is included in the image sensor illustrated in FIG. 17.

FIG. 20 is a plan view that schematically illustrates a substrate of the image sensor illustrated in FIG. 17.

FIG. 21 is a rear perspective view that conceptually illustrates a reset transistor and a first gain control transistor illustrated in FIG. 20.

FIG. 22 is a rear perspective view that conceptually illustrates a precharge transistor illustrated in FIG. 20.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to example embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, or the like, illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, or the like, may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

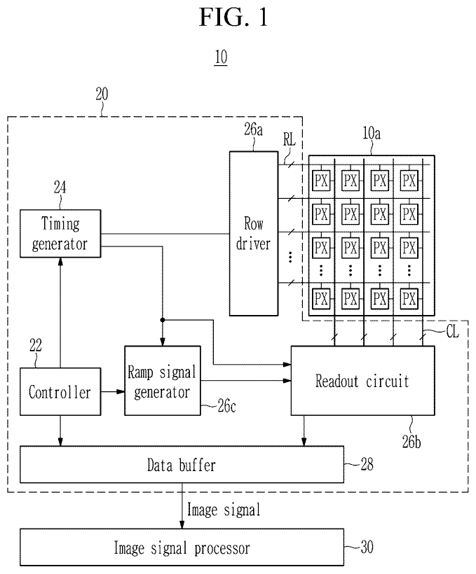

Hereinafter, an image sensor and a manufacturing method of the same according to some example embodiments will be described in detail with reference to FIG. 1 to FIG. 16.

FIG. 1 is a block diagram that schematically illustrates an example of an image sensor 10.

Referring to FIG. 1, an image sensor 10 according to some example embodiments may include a pixel array 10a, and a logic circuit 20 that controls the pixel array 10a. The logic circuit 20 is a circuit configured to control the pixel array 10a and may include, for example, a controller 22, a timing generator 24, a row driver 26a, a readout circuit 26b, a ramp signal generator 26c, and a data buffer 28. The image sensor 10 may further include an image signal processor 30. In some example embodiments, the image signal processor 30 may be disposed outside the image sensor 10.

The image sensor 10 may generate an image signal by converting light received from an outside into an electric signal, and the image signal generated by the image sensor 10 may be provided to the image signal processor 30.

The image sensor 10 may be mounted on an electronic device with an image and/or light sensing function. For example, the image sensor 10 may be mounted on electronic devices such as cameras, smartphones, wearable devices, internet of things (IoT) devices, home appliance devices, tablets, personal digital assistants (PDA), portable multimedia players (PMP), navigations, drones, and/or advanced driver assistance systems (ADAS). In some example embodiments, the image sensor 10 may be mounted on an electronic device provided as a part of a vehicle, furniture, a manufacturing facility, a door, and/or various measuring devices. However, example embodiments are not limited thereto.

The pixel array 10a may include a plurality of pixel regions PX, and a plurality of row lines RL and a plurality of column lines CL respectively connected to the plurality of pixel regions PX.

In some example embodiments, each pixel region PX may include at least one photoelectric conversion device. The photoelectric conversion device may detect incident light and convert the incident light into the electric signal, for example, the plurality of analog pixel signals, according to an amount of light. The photoelectric conversion device may be a photodiode, a photo transistor, a photo gate, or a pinned photo diode (PPD). In some example embodiments, the photoelectric conversion device may be a single-photon avalanche diode (SPAD) applied to a 3D sensor pixel. A level of the analog pixel signal output from the photoelectric conversion device may be proportional to an amount of light provided to each pixel region PX or an amount of charges output from the photoelectric conversion device.

The plurality of row lines RL may extend in one direction and be connected to the plurality of pixel regions PX arranged in the one direction. For example, a control signal output from the row driver 26a to the row line RL may be transmitted to a gate of a transistor of the plurality of pixel regions PX that is connected to the row line RL. The column line CL may extend in a crossing direction that is transverse to or crosses the one direction and may be connected to the plurality of pixel regions PX arranged in the crossing direction that is transverse to the one direction. The plurality of pixel signals output from the plurality of pixel regions PX may be transmitted to the readout circuit 26b through the plurality of column lines CL.

In some example embodiments the plurality of pixel regions PX may be grouped in a form of a plurality of columns and a plurality of rows to form one unit pixel. For example, the plurality of pixel regions PX arranged in an extension direction of the row line RL and/or the plurality of pixel regions PX arranged in an extension direction of the column line CL may form one unit pixel. For example, one unit pixel may include a plurality of pixels arranged in a form of two columns and two rows, and one unit pixel may output one analog pixel signal. However, example embodiments are not limited thereto and various modifications are possible. In some example embodiments, one pixel region PX may constitute one unit pixel.

In some example embodiments, each pixel region PX may include a pixel circuit that processes the charge generated by the photoelectric conversion device and outputs the electric signal. The pixel circuit may include a transfer transistor, a reset transistor, a selection transistor, a driving transistor, or the like. Example embodiments are not limited thereto and the pixel circuit may have any of various structures.

The controller 22 may generally control the timing generator 24, the row driver 26a, the readout circuit 26b, the ramp signal generator 26c, and the data buffer 28 included in the image sensor 10. For example, the controller 22 may control an operation timing by using a control signal. In some example embodiments, the controller 22 may receive a mode signal indicating an imaging mode from an application processor and generally control the image sensor 10 based on the received mode signal.

The timing generator 24 may generate a signal that serves as a reference for the operation timing of the image sensor 10. The timing generator 24 may provide a control signal that controls the timing of the row driver 26a, the readout circuit 26b, and the ramp signal generator 26c.

The row driver 26a may generate a control signal to drive the pixel array 10a in response to the control signal of the timing generator 24, and may provide the control signal to the plurality of pixel regions PX of the pixel array 10a through the plurality of row lines RL. For example, the row driver 26a may generate a transfer signal that controls the transfer transistor, a reset control signal that controls the reset transistor, and a selection control signal that controls the selection transistor, and provide the transfer signal, the reset control signal, and the selection signal to the pixel array 10a.

The readout circuit 26b may convert a pixel signal (or an electric signal) output through the corresponding column line CL into a pixel value representing the amount of light. The ramp signal generator 26c may generate a reference signal or a ramp signal and transmit the reference signal or the ramp signal to the readout circuit 26b. For example, the readout circuit 26b may convert the pixel signal to the pixel value by comparing the ramp signal and the pixel signal. The pixel value may be an image data with a plurality of bits.

The data buffer 28 may store the pixel value of the pixel region PX transmitted from the readout circuit 26b and may output the stored pixel value in response to a signal from the controller 22.

The image signal processor 30 may perform an image signal processing on the image signal received from the data buffer 28. For example, the image signal processor 30 may receive the plurality of image signals from the data buffer 28 and generate one image by combining the received image signals.

Example embodiments are not limited to the above descriptions, and a structure, a type, or the like of the image sensor 10 may be variously modified.

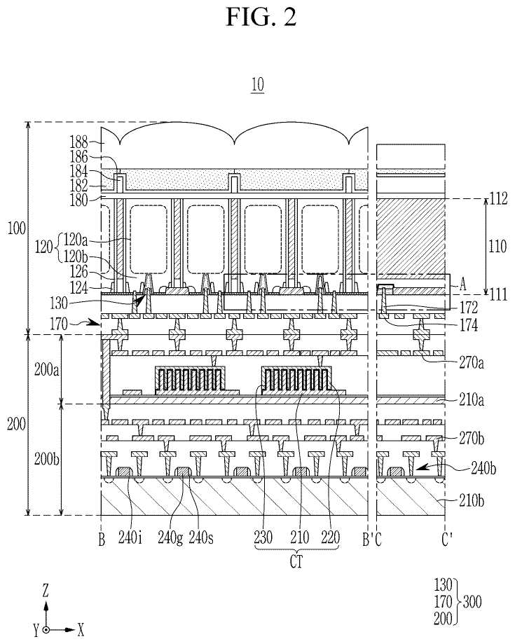

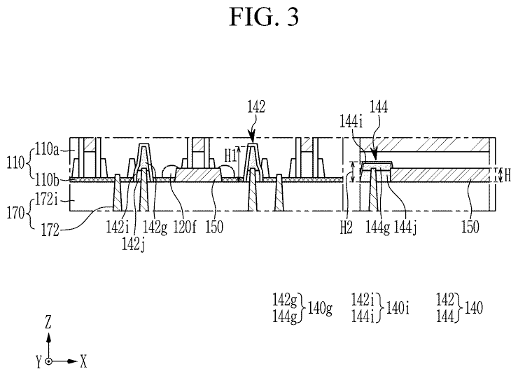

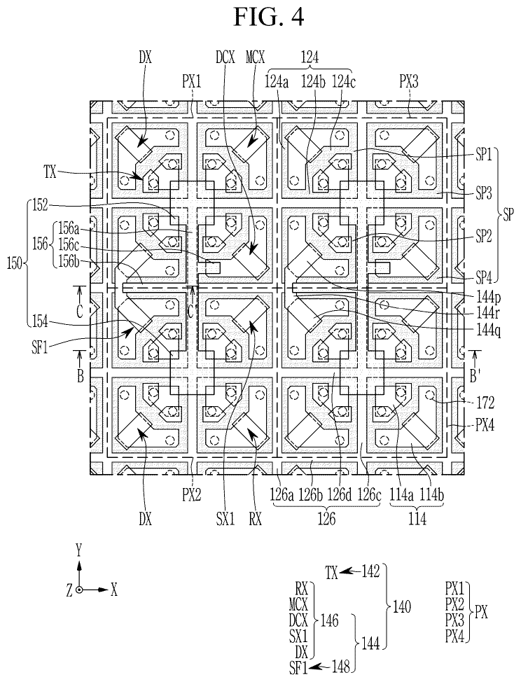

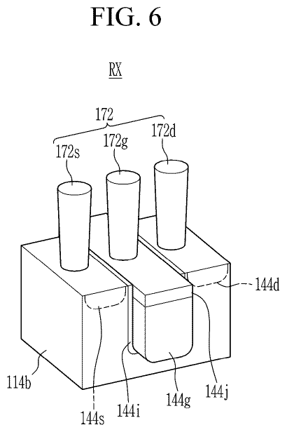

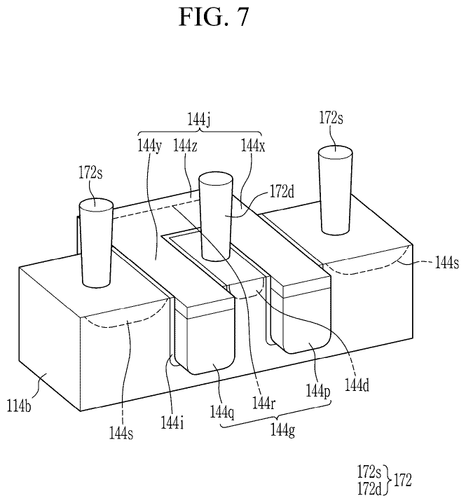

FIG. 2 is a partial cross-sectional view that illustrates an image sensor 10 according to some example embodiments. FIG. 3 is an enlarged cross-sectional view that illustrates a portion A in FIG. 2. FIG. 4 is a plan view that schematically illustrates a substrate 110 of the image sensor 10 illustrated in FIG. 2. FIG. 2 is a cross-sectional view taken along a line B-B′ and a line C-C′ in FIG. 4. FIG. 4 is a rear plan view that illustrates a first surface 111 of the substrate 110 adjacent to a wiring portion 170. For a clear understanding and simple illustration, in FIG. 4, a surface insulation layer 110b is omitted. For a clear understanding, in FIG. 4, positions of first contact vias 172 that are electrically connected to a first transistor 142, and a source region 144s (refer to FIG. 6 and FIG. 7) and a drain region 144d (refer to FIG. 6 and FIG. 7) of a second transistor 144 are schematically illustrated as a dotted line.

Referring to FIG. 2 to FIG. 4, in some example embodiments, an image sensor 10 may include a substrate 110 having a first surface 111 and a second surface 112 that are opposite to each other, and a plurality of pixel regions PX. At least one of the plurality of pixel regions PX includes a photoelectric conversion portion 120 and a pixel circuit 130 adjacent to the first surface 111 of the substrate 110. The image sensor 10 or the substrate 110 may include an isolation portion 126 that includes a portion disposed to correspond to a boundary of the plurality of pixel regions PX. The photoelectric conversion portion 120 may be disposed in the substrate 110. In some example embodiments, the pixel circuit 130 may include a plurality of transistors 140 and/or a connection wiring 150, and the plurality of transistors 140 and/or the connection wiring 150 may have a buried structure that is buried inside the substrate 110. The phrase that the transistor 140 has the buried structure may refer to some example embodiments in which at least a partial portion (e.g., an entire portion) of a gate electrode 140g may be disposed inside the substrate 110.

In some example embodiments, the substrate 110 may include a semiconductor substrate 110a that includes or is formed of a semiconductor material. For example, the semiconductor substrate 110a may include a bulk substrate that includes or is formed of a semiconductor material, a substrate that includes a bulk substrate and an epitaxial layer on the bulk substrate, or a semiconductor-on-insulator. In this instance, the semiconductor material included in the semiconductor substrate 110a may include a second conductivity type dopant to have a second conductivity type (e.g., a p-type or an n-type) that is opposite to a conductivity type of a first conductivity type well 120a.

The semiconductor material included in the semiconductor substrate 110a may include or be formed of at least one of a group IV semiconductor, a group III-V compound semiconductor, or a group II-VI compound semiconductor. For example, the semiconductor material that is included in the semiconductor substrate 110a may include or be formed of at least one of Si, Ge, SiGe, SiC, GaAs, InAs, GaP, InP, InSb, InGaAs, ZnTe, or CdS. For example, the bulk substrate may be a single-crystalline or polycrystalline semiconductor substrate and may include or be formed of Si, Ge, or SiGe. In some example embodiments, the semiconductor-on-insulator may be a silicon-on-insulator (SOI), a germanium-on-insulator (GOI), or a silicon-germanium-on-insulator (SGOI).

A doping region may be disposed at a portion adjacent to the first surface 111 of the substrate 110 (e.g., in a partial portion of the semiconductor substrate 110a adjacent to the first surface 111). The doping region may include a floating diffusion region 120f, a ground region, or the like. For simple illustration, in FIG. 2 to FIG. 4, in the floating diffusion region 120f is illustrated and the ground region is omitted.

The floating diffusion region 120f may have a first conductivity type opposite to the second conductivity type of the semiconductor substrate 110a, and charges generated by the photoelectric conversion portion 120 may be accumulated in the floating diffusion region 120f. The floating diffusion region 120f may be disposed in a partial portion of a first active region 114a. A position, an electrical connection structure, or the like of the floating diffusion region 120f will be described later in more detail. The ground region may have a second conductivity type the same as a conductivity type of the semiconductor substrate 110a, and may have a doping concentration higher than a doping concentration of the substrate 110 or a second conductivity type well 120b. A ground voltage may be applied to the ground region. The ground region may be disposed in a partial portion of an active region 114.

However, example embodiments are not limited thereto. The floating diffusion region 120f and/or the ground region may be omitted. In some example embodiments, an additional doping region other than the floating diffusion region 120f and/or the ground region may be further included.

In some example embodiments, a surface insulation layer 110b may be further included. The surface insulation layer 110b may be disposed on a first surface of the semiconductor substrate 110a that is adjacent to the first surface 111 of the substrate 110. For example, the surface insulation layer 110b may cover a surface (e.g. an outer surface) of the semiconductor substrate 110a, a surface (e.g., an outer surface) of a device isolation portion 124, and/or a surface (e.g. an outer surface) of the isolation portion 126 that is adjacent to the first surface 111 of the substrate 110. The surface insulation layer 110b may be an etch stopper layer or an end point detection (EPD) layer. However, example embodiments are not limited thereto. In some example embodiments, the substrate 110 may include or be formed of the semiconductor substrate 110a, and the surface insulation layer 110b may be omitted.

In some example embodiments, the plurality of pixel regions PX may include a first pixel region PX1, a second pixel region PX2, a third pixel region PX3, and a fourth pixel region PX4. The first pixel region PX1 and the second pixel region PX2 may be adjacent to each other in a first direction (a Y-axis direction in the drawings). The third pixel region PX3 and the fourth pixel region PX4 may be adjacent to the first pixel region PX1 and the second pixel region PX2, respectively, in a second direction (an X-axis direction in the drawings) that is transverse to or crosses the first direction (the Y-axis direction in the drawings).

In one operation (e.g., a global shutter operation) of the image sensor 10, the first pixel region PX1, the second pixel region PX2, the third pixel region PX3, and the fourth pixel region PX4 may constitute one unit pixel that outputs one pixel signal. In the global shutter operation, an image may be implemented without distortion. In another operation (e.g., a rolling shutter operation) of the image sensor 10, each pixel region PX, each sub-pixel region SP, or a part of a plurality of sub-pixel regions SP included in each pixel region PX may constitute one unit pixel that outputs one pixel signal. In the rolling shutter operation, resolution may be enhanced. However, example embodiments are not limited thereto. Various modifications are possible.

The photoelectric conversion portion 120 configured to convert light to an electrical signal may be disposed in the substrate 110.

For example, the photoelectric conversion portion 120 may include a first conductivity type well 120a and a second conductivity type well 120b. The first conductivity type well 120a may include a first conductivity type dopant to have a first conductivity type (e.g., an n-type or a p-type) that is opposite to a conductive type of the semiconductor substrate 110a. The second conductivity type well 120b may include a second conductivity type dopant to have a second conductivity type (e.g., a p-type or an n-type) that is opposite to the first conductive type. The first conductivity type well 120a may be formed by doping the first conductivity type dopant to a portion of the semiconductor substrate 110a. The second conductivity type well 120b may be formed by doping the second conductivity type dopant to a portion of the semiconductor substrate 110a that is adjacent to the first surface 111 of the substrate 110. In some example embodiments, the second conductivity type well 120b may be formed of a portion of the semiconductor substrate 110a where the first conductivity type well 120a is not positioned. A photodiode may be constituted by a pn junction of the first conductivity type well 120a and the second conductivity type well 120b. The photoelectric conversion portion 120 may generate and accumulate charges in proportion to an amount of light provided to each pixel region PX. In some example embodiments, the second conductivity type well 120b may be omitted.

The photoelectric conversion portion 120 may be disposed to correspond to each pixel region PX and/or each sub-pixel region SP. For example, the isolation portion 126 may pass through or penetrate at least a partial portion of the substrate 110 between the plurality of pixel regions PX. One or more photoelectric conversion portions 120 may be disposed in each of the plurality of pixel regions PX.

In some example embodiments, in a cross-sectional view, the isolation portion 126 may pass through or penetrate at least a partial portion of the substrate 110 in a thickness direction (a Z-axis direction in the drawings). In a plan view, the isolation portion 126 may pass through or penetrate a partial portion (e.g., an inner portion) of the device isolation portion 124.

The isolation portion 126 may be disposed in a first trench that has a relatively large depth. For example, the first trench may be a deep trench (DT), and the isolation portion 126 may be a deep trench isolation (DTI). In some example embodiments, the isolation portion 126 may include a front deep trench isolation (FDTI) that includes a portion adjacent to the first surface 111 of the substrate 110 and/or a back deep trench isolation (BDTI) that includes a portion adjacent to the second surface 112 of the substrate 110. In the drawing, it is illustrated as an example that the isolation portion 126 includes the front deep trench isolation and entirely penetrates the semiconductor substrate 110a, but example embodiments are not limited thereto.

In a plan view, the isolation portion 126 may include a first isolation portion 126a that extends in the first direction (the Y-axis direction in the drawings) and a second isolation portion 126b that extends in the second direction (the X-axis direction in the drawings). For example, in a plan view, the isolation portion 126 may include a portion having a lattice shape to correspond to the boundary of the plurality of pixel regions PX. Accordingly, in a plan view, each pixel region PX may be surrounded by a pair of first isolation portions 126a and a pair of second isolation portions 126c.

In some example embodiments, the isolation portion 126 may further include an inner isolation portion 126c or 126d that is disposed inside the pixel region PX. For example, the inner isolation portions 126c and 126d may include a first inner isolation portion 126c that extends in the first direction (the Y-axis direction in the drawings) and a second inner isolation portion 126d that extends in the second direction (the X-axis direction in the drawings).

In some example embodiments, the inner isolation portions 126c and 126d may define sub-pixel regions SP in the pixel region PX. For example, in a plan view, the inner isolation portions 126c and 126d may have a lattice shape to correspond to a boundary of the plurality of sub-pixel regions SP. Accordingly, in a plan view, each sub-pixel region SP may be surrounded by the first isolation portion 126a, the second isolation portion 126b, the first inner isolation portion 126c, and the second inner isolation portion 126d.

In some example embodiments, the plurality of sub-pixel regions SP in each pixel region PX may include a first sub-pixel region SP1 and a second sub-pixel region SP2 that are adjacent to each other in the first direction (the Y-axis direction in the drawings), and a third sub-pixel region SP3 and a fourth sub-pixel region SP4 that are adjacent to the first sub-pixel region SP1 and the second sub-pixel region SP2, respectively, in the second direction (the X-axis direction in the drawings) that is transverse to or crosses the first direction (the Y-axis direction in the drawings). For example, in some example embodiments, each pixel region PX may include four sub-pixel regions SP. However, example embodiments are not limited thereto. A number, an arrangement, or the like of the plurality of sub-pixel regions SP in each pixel region PX may be variously modified.

For example, the inner isolation portions 126c and 126d may define a portion where the photoelectric conversion portion 120 (e.g., the first conductivity type well 120a) is disposed inside the pixel region PX, and one photoelectric conversion portion 120 (e.g., one first conductivity type well 120a) may be included in each sub-pixel region SP. However, example embodiments are not limited thereto. In some example embodiments, the inner isolation portions 126c and 126d may be omitted. In some example embodiments, one or a plurality of photoelectric conversion portions 120 (e.g., one or a plurality of first conductivity type wells 120a) may be included in the pixel region PX or the sub-pixel region SP. A position, a planar shape, or the like of the photoelectric conversion portion 120 (e.g., the first conductivity type well 120a) may be variously modified.

The isolation portion 126 may include an insulating material layer. The insulating material layer of the isolation portion 126 may include or be formed of at least one of silicon oxide, silicon nitride, or silicon oxynitride, and may include a single layer or a plurality of layers. However, example embodiments are not limited thereto. A material of the insulating material layer of the isolation portion 126 may be variously modified.

In some example embodiments, the isolation portion 126 may further include a conductive layer. For example, the conductive layer of the isolation portion 126 may include or be formed of a semiconductor material (e.g., silicon). A dark current may be improved through a hole accumulation induced by a negative voltage applied to the conductive layer of the isolation portion 126. However, example embodiments are not limited thereto. The negative voltage might not be applied to the conductive layer of the isolation portion 126, or the isolation portion 126 might not include the conductive layer.

A sidewall doping region may be disposed at a portion of the semiconductor substrate 110a that is adjacent to the isolation portion 126. Sidewall doping regions may be disposed at portions adjacent to both sidewalls of the isolation portion 126, respectively. The sidewall doping region may improve the dark current, together with the conductive layer of the isolation portion 126. The sidewall doping region may have the second conductivity type (the p-type or the n-type) that is the same as a conductivity type of the semiconductor substrate 110a. For example, the sidewall doping region may have the p-type. For example, the sidewall doping region may include boron, aluminum, gallium, indium, or the like as a p-type dopant.

In some example embodiments, the device isolation portion 124 may be disposed in a second trench that has a relatively small depth to separate, divide, or define the active region 114 in each pixel region PX. For example, the second trench may be a shallow trench (ST), and the device isolation portion 124 may be a shallow trench isolation (STI). In a cross-sectional view, the device isolation portion 124 may define the active region 114 in a portion adjacent to the first surface 111 of the substrate 110. In the drawings, a boundary of the device isolation portion 124 and the isolation portion 126 is illustrated for a clearer understanding. However, in some embodiments, the boundary of the device isolation portion 124 and the isolation portion 126 may not be confirmed and the device isolation portion 124 and the isolation portion 126 may form an integral structure at a portion adjacent to first surface 111 of the substrate 110.

In a plan view, the device isolation portion 124 may include a first device isolation portion 124a, a second device isolation portion 124b, and a third device isolation portion 124c. The first device isolation portion 124a may extend in the first direction (the Y-axis direction in the drawings), and the second isolation portion 126b may extend in the second direction (the X-axis direction in the drawings). The third device isolation portion 124c may cross an inside of the sub-pixel region SP to connect the first device isolation portion 124a and the second device isolation portion 124b.

The first device isolation portion 124a may be disposed at portions where the first isolation portion 126a and the first inner isolation portion 126c that extend in the first direction (the Y-axis direction in the drawings) are disposed. The second device isolation portion 124b may be disposed at portions where the second isolation portion 126b and the second inner isolation portion 126d that extend in the second direction (the X-axis direction in the drawings) are disposed. For example, in a plan view, the first device isolation portion 124a and the second device isolation portion 124b may have a lattice shape configured to separate, divide, or define the plurality of pixel regions PX and/or the plurality of sub-pixel regions SP.

The third device isolation portion 124c might not overlap the isolation portion 126 and may separate, divide, or define the active region 114 in the sub-pixel region SP. By the third device isolation portion 124c, in each sub-pixel region SP, the active region 114 may include a first active region 114a where a first transistor 142 is disposed and a second active region 114b where a second transistor 144 is disposed. In FIG. 4, it is illustrated as an example that, in a plan view, the third device isolation portion 124c includes a first portion, a second portion, and an inclined portion. The first portion may be adjacent to the second device isolation portion 124b and extend in the first direction (the Y-axis direction in the drawings). The second portion may be adjacent to the first device isolation portion 124a and extend in the second direction (the X-axis direction in the drawings). The inclined portion may connect the first portion and the second portion in a direction inclined to the first direction and the second direction. Accordingly, areas of the first active region 114a where the first transistor 142 is disposed and the second active region 114b where the second transistor 144 is disposed may be sufficiently secured and the first active region 114a and the second active region 114b may be stably separated, divided, or defined. However, example embodiments are not limited thereto. A shape, an arrangement, or the like of the third device isolation portion 124c may be variously modified.

The device isolation portion 124 may include or be formed of at least one of silicon oxide, silicon nitride, or silicon oxynitride, and the device isolation portion 124 may include a single layer or a plurality of layers. However, example embodiments are not limited thereto. Accordingly, a material of the device isolation portion 124 may be variously modified, or the device isolation portion 124 may be omitted.

In FIG. 2, it is illustrated as an example that a surface (e.g. an outer surface) of the device isolation portion 124 and a surface (e.g. an outer surface) of the isolation portion 126, which are adjacent to the first surface of the semiconductor substrate 110a adjacent to the first surface 111 of the substrate 110, are disposed on the same plane as the first surface of the semiconductor substrate 110a. However, example embodiments are not limited thereto. The first surface of the semiconductor substrate 110a may be disposed on a different plane from the surface of the device isolation portion 124 and/or the surface the isolation portion 126.

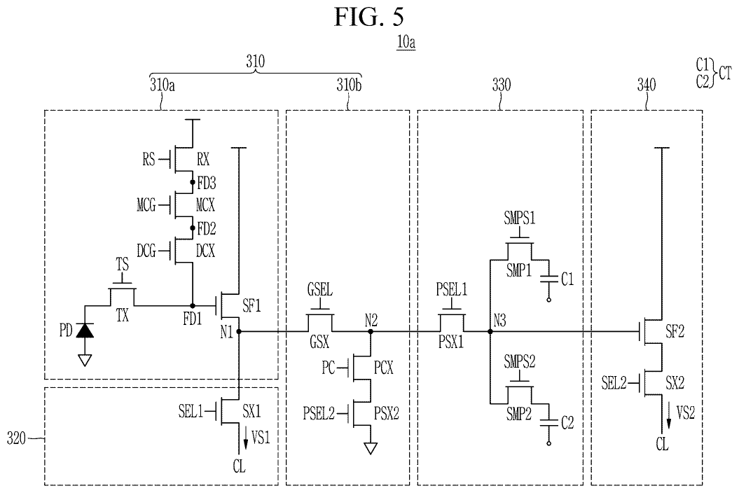

The pixel circuit 130 may be disposed to be adjacent to the first surface 111 of the substrate 110. The pixel circuit 130 will be described later in more detail with reference to FIG. 5.

A wiring portion 170 that is electrically connected to the pixel circuit 130 may be disposed on the first surface 111 of the substrate 110. For example, the wiring portion 170 may be disposed to be adjacent to the first surface 111 of the substrate 110, which is opposite to the second surface 112 of the substrate 110 to which the light is incident, and accordingly, the wiring portion 170 might not be disposed in a path of the light incident to the image sensor 10. Accordingly, light interference caused by the wiring portion 170 may be minimized.

The wiring portion 170 may include one or a plurality of wiring layers that are electrically connected to the pixel circuit 130 through a contact via that passes through or penetrates an interlayer insulation layer. For example, the wiring portion 170 may include at least a first contact via 172. The first contact via 172 may be electrically connected to (e.g., directly connected to) the pixel circuit 130 (e.g., a plurality of transistors 140) through passing through or penetrating a first interlayer insulation layer 172i. The wiring portion 170 may include a first wiring layer 174 that is electrically connected to the first contact via 172 and one or a plurality of second contact vias and/or one or a plurality of second wiring layers that are disposed on the first wiring layer 174. The second contact via may pass through or penetrate a second interlayer insulation layer to electrically connect the first wiring layer 174 and the second wiring layer or electrically connect second wiring layers that are adjacent to each other. The first contact via 172, the first wiring layer 174, the second contact via, and the second wiring layer of the wiring portion 170 may be connected to form a desired circuit. The first contact via 172 may be formed in the same process as the first wiring layer 174, or may be formed in a separate process from the first wiring layer 174. The second contact via may be formed in the same process as the second wiring layer, or may be formed in a separate process from the second wiring layer.

The interlayer insulation layer (e.g., the first interlayer insulation layer 172i and/or the second interlayer insulation layer) of the wiring portion 170 may include or be formed of an insulating material. For example, the interlayer insulation layer (e.g., the first interlayer insulation layer 172i and/or the second interlayer insulation layer) of the wiring portion 170 may include or be formed of silicon oxide, silicon nitride, silicon oxynitride, and/or a low dielectric constant material. The low dielectric constant material may be a material having a dielectric constant lower than a dielectric constant of silicon oxide.

The contact via (e.g., the first contact via 172 and/or the second contact via) of the wiring portion 170 may include or be formed of at least one of a metal, a metal alloy, metal nitride, metal silicide, or a doped semiconductor material. The metal or the metal alloy may include or be formed of at least one of tungsten, molybdenum, aluminum, copper, or cobalt, and the metal nitride may include or be formed of at least one of tungsten nitride, molybdenum nitride, titanium nitride, or tantalum nitride. The contact via of the wiring portion 170 may further include metal oxide or metal oxynitride in which the above material is oxidized. The contact via of the wiring portion 170 may include a single layer or a plurality of layers.

However, example embodiments are not limited thereto. The interlayer insulation layer of the wiring portion 170 may include or be formed of any of various insulating materials, and the contact via of the wiring portion 170 may include or be formed of any of various conductive materials.

A horizontal insulation layer 180, a color filter 182, a filter separator 184, a protection layer 186, and a micro lens 188 may be disposed on the second surface 112 of the substrate 110.

More particularly, the horizontal insulation layer 180 may be disposed on the second surface 112 of the substrate 110. The horizontal insulation layer 180 may be disposed to cover the second surface 112 of the substrate 110 and the isolation portion 126. The horizontal insulation layer 180 may act as a kind of a planarization layer configured to planarize a surface so that the color filter 182, the micro lens 188, or the like disposed on the horizontal insulation layer 180 may be stably formed.

The horizontal insulation layer 180 may include or be formed of any of various insulating materials. For example, the horizontal insulation layer 180 may include or be formed of oxide, nitride, oxynitride, or fluoride including at least one of hafnium, zirconium, aluminum, tantalum, titanium, yttrium, cerium, lanthanum, neodymium, praseodymium, ytterbium, or silicon. For example, the horizontal insulation layer 180 may act as an anti-reflection layer, but example embodiments are not limited thereto.

In some example embodiments, the horizontal insulation layer 180 may include a plurality of layers including different materials and having different thicknesses. For example, in the horizontal insulation layer 180, a first horizontal insulation layer adjacent to the second surface 112 of the substrate 110 may be a fixed charge layer having a negative fixed charge. Accordingly, the dark current may be improved by a hole accumulation at a periphery of the fixed charge layer. In some example embodiments, the first horizontal insulation layer may include or be formed of metal oxide or metal fluoride including at least one of hafnium, zirconium, aluminum, tantalum, titanium, or yttrium. For example, the horizontal insulation layer 180 or the anti-reflection layer may include a first horizontal insulation layer including hafnium oxide, a second horizontal insulation layer including silicon oxide or silicon nitride, and a third horizontal insulation layer including hafnium oxide.

However, example embodiments are not limited to thereto, and a number, a thickness, or the like of layers included in the horizontal insulation layer 180 may be variously modified. In some example embodiments, a structure configured to reflect light may be disposed at the second surface 112 of the substrate 110. For example, a nanoporous structure that has a nanometer-level size may be formed at the second surface 112 of the substrate 110 by using laser or etching, accordingly reflecting the light. The nanometer-level size may refer to a size (e.g., an average width, an average diameter, or an average pitch) of less than 1 um. Accordingly, the anti-reflection layer may be omitted in the horizontal insulation layer 180 and a manufacturing process may be simplified. However, example embodiments are not limited thereto. In some example embodiments, when the structure configured to reflect the light is disposed at the second surface 112 of the substrate 110, the horizontal insulation layer 180 may include the anti-reflection layer.

The filter separator 184 may be disposed on the horizontal insulation layer 180. In some example embodiments, the filter separator 184 may surround at least a partial portion of the color filter 182. For example, the filter separator 184 may have a lattice structure that is the same as or similar to the lattice structure of the isolation portion 126, but example embodiments are not limited thereto. The filter separator 184 may be referred to as a fence pattern or a grid pattern.

The filter separator 184 may hinder or prevent light that is incident obliquely into one color filter 182 in one of the plurality of pixel regions PX from entering another color filter 182 in adjacent pixel region PX. Accordingly, a crosstalk between the plurality of pixel regions PX may be hindered or prevented.

In some example embodiments, the filter separator 184 may include or be formed of a material having a refractive index smaller than a refractive index of the color filter 182 or silicon oxide, or a material having a refractive index of about 1.0 to about 1.4. When the filter separator 184 includes a material with a small refractive index in the above, the light incident on the filter separator 184 may be totally reflected and directed toward an inside of the pixel region PX.

For example, the filter separator 184 may include or be formed of polymethyl methacrylate (PMMA), silicon acrylate, cellulose acetate butyrate (CAB), silica, or fluorine-silicon acrylate (FSA). For example, the filter separator 184 may include or be formed of a polymer material in which silica particles are dispersed. However, example embodiments are not limited to thereto, and the filter separator 184 may include a material different from the above material.

The color filter 182 may be disposed on the horizontal insulation layer 180. The plurality of color filters 182 may be separated from each other by the filter separator 184. A plurality of color filters 182 may include, for example, a green filter, a blue filter, and a red filter. In some example embodiments, the plurality of color filters 182 may include a cyan filter, a magenta filter, a yellow filter, an infrared filter to allow infrared light to pass through, or the like. In some embodiment, a pixel region PX where all visible light is incident may be provided.

The protection layer 186 may be disposed on the color filter 182 and/or the filter separator 184. In FIG. 2, it is illustrated as an example that the protection layer 186 is disposed between the filter separator 184 and the color filter 182 on the filter separator 184. The protection layer 186 may include or be formed of any of various materials such as an organic material, silicon oxide, silicon oxynitride, aluminum oxide, or the like. However, example embodiments are not limited to a material of the protection layer 186. The protection layer 186 may be omitted, or the protection layer 186 may be disposed on the color filter 182 and the filter separator 184.

The micro lens 188 that is disposed on the color filter 182 and/or the protection layer 186 may include or be formed of a portion having a convex shape to converge or concentrate light incident to the pixel region PX. The micro lens 188 may include or be formed of any or various resin materials, for example, a styrene-based resin, an acryl-based resin, a styrene-acryl copolymer resin, a siloxane-based resin, or the like.

However, example embodiments are not limited to thereto, and a shape, a material, or the like of the micro lens 188 may be variously modified. In some example embodiments, a meta lens may be included instead of the micro lens 188. The meta lens may include a nano structure of a nano rod or a nano pillar that has a nanometer-level size. In the meta lens, by a meta surface including meta atoms that are smaller than a wavelength of light uniformly or periodically, a direction of incident light may be changed so that the light reach a specific point. Accordingly, the meta lens may act as a lens. The meta lens or the nano structure may include or be formed of Si, SiN, GaN, TiO₂, or the like.

In FIG. 2, it is illustrated as an example that one micro lens 188 corresponds to each pixel region PX. However, example embodiments are not limited thereto. In some example embodiments, one micro lens 188 may correspond to a plurality of pixel regions PX. In some example embodiments, one micro lens 188 may correspond to each sub-pixel region SP. In some example embodiments, a protective layer or the like may be disposed on an outer surface of the micro lens 188.

In FIG. 2, it is illustrated as an example that the filter separator 184 corresponds to each pixel region PX. However, example embodiments are not limited thereto. In some example embodiments, the filter separator 184 may correspond to each sub-pixel region SP. Other various modifications are possible.

In some example embodiments, in a plan view, a relative position between the pixel region PX and the color filter 182 and/or a relative position between the pixel region PX and the micro lens 188 may be different from each other in a central portion of the image sensor 10 and in an edge portion of the image sensor 10. For example, in plan view, an area (e.g. a planar area) of the color filter 182 that overlaps the pixel region PX and/or an area (e.g. a planar area) of the micro lens 188 that overlaps the pixel region PX may be smaller in the edge region of the image sensor 10 than in the central region of the image sensor 10. For example, an area (e.g. a planar area) of the color filter 182 that overlaps the pixel region PX and/or an area (e.g. a planar area) of the micro lens 188 that overlaps the pixel region PX may decrease from the central region of the image sensor 10 to the edge region of the image sensor 10.

By adjusting the relative position between the pixel region PX and the color filter 182 and/or the relative position between the pixel region PX and the micro lens 188, an amount of the light that reaches the photoelectric conversion portion 120 of the pixel region PX may be maximized. For example, the micro lens 188, the color filter 182, and the photoelectric conversion portion 120 of the pixel region PX may be disposed to be overlapped in a direction in which light passes. Since the light is incident obliquely in the edge region of the image sensor 10, the relative position between the pixel region PX and the color filter 182 and/or the relative position between the pixel region PX and the micro lens 188 may be adjusted so that the light that is incident obliquely reaches the photoelectric conversion portion 120 of the pixel region PX to a large amount.

An additional wiring portion 200 may be further disposed on a photoelectric conversion substrate 100 (e.g., the wiring portion 170). In some example embodiments, the pixel circuit 130, the wiring portion 170, and the additional wiring portion 200 may be a circuit region 300 that controls an operation of the image sensor 10.

As in the above, the image sensor 10 may have a multi-layered stacking structure that include the photoelectric conversion substrate 100 and the additional wiring portion 200. When the photoelectric conversion substrate 100 and the additional wiring portion 200 are included as in the above, congestion of wirings, circuit elements, or the like that are included in the pixel circuit 130, the wiring portion 170, and the additional wiring portion 200 that constitute the circuit region 300 may be reduced. Accordingly, an integration degree and/or performance of the image sensor 10 may be enhanced.

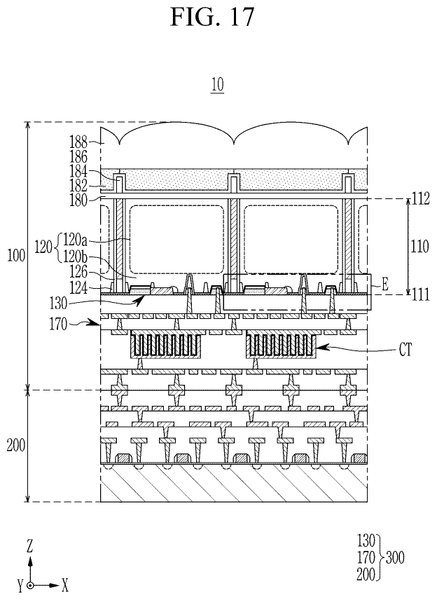

In FIG. 2, it is illustrated as an example that the additional wiring portion 200 includes a first additional wiring portion 200a and a second additional wiring portion 200b that are sequentially disposed on a first surface of the photoelectric conversion substrate 100 and the image sensor 10 has a three-layered stacking structure. However, example embodiments are not limited thereto. the image sensor 10 may have a two-layered stacking structure or a four-layered or more stacking structure. Some example embodiments of an image sensor 10 that has the two-layered stacking structure will be described later in detail with reference to FIG. 17 to FIG. 22.

In FIG. 2, it is illustrated as an example that the wiring portion 170 and the first additional wiring portion 200a may be bonded by hybrid bonding including metal bonding and insulation-layer bonding, and the first additional wiring portion 200a includes a substrate 210a (e.g., a semiconductor substrate), but example embodiments are not limited thereto. In some example embodiments, the wiring portion 170 and the first additional wiring portion 200a may be bonded by insulation-layer bonding, and then, a connection member or the like configured to connect the wiring portion 170 and the first additional wiring portion 200a may be formed. The first additional wiring portion 200a and the second additional wiring portion 200b may be bonded by hybrid bonding including metal bonding and insulation-layer bonding, but example embodiments are not limited thereto.

In the image sensor 10 according to some example embodiments, the light incident from an outside may be converged or concentrated by the micro lens 188 and incident on the photoelectric conversion portion 120 through the color filter 182. The light incident on the photoelectric conversion portion 120 may be converted into an electric signal according to an amount of the light.

The image sensor 10 according to some example embodiments may have a global shutter structure capable of performing the global shutter operation. For example, the image sensor 10 may have a hybrid global shutter structure capable of performing the global shutter operation and the rolling shutter operation. Accordingly, the image sensor 10 may include a memory device that is electrically connected to the pixel circuit 130. Entire pixel regions PX may simultaneously store signals by the memory device and a moving image may be implemented without distortion.

Hereinafter, referring to FIG. 2 to FIG. 5, a circuit diagram of the image sensor 10 (e.g., a pixel array 10a) that has the global shutter structure (e.g., the hybrid global shutter structure) will be described and the pixel circuit 130 and the additional wiring portion 200 according to some example embodiments will be described in more detail.

FIG. 5 is a circuit diagram of a pixel array 10a that is included in the image sensor 10 illustrated in FIG. 2.

Referring to FIG. 5 together with FIG. 2 to FIG. 4, the pixel array 10a of the image sensor 10 that has the hybrid global shutter structure may include a photoelectric charge generation circuit 310, a first pixel signal circuit 320, a sampling circuit 330, and a second pixel signal circuit 340.

The photoelectric charge generation circuit 310 may include a photoelectric conversion portion PD, a transfer transistor TX, a reset transistor RX, a gain control transistor DCX or MCX, a driving transistor (e.g., a first driving transistor SF1), a global shutter selection transistor GSX, a precharge transistor PCX, and a precharge selection transistor (e.g., a second precharge selection transistor PSX2). The photoelectric charge generation circuit 310 may transfer photoelectric charges generated by the photoelectric conversion portion PD to the first pixel signal circuit 320 or the sampling circuit 330. The photoelectric conversion portion PD illustrated in FIG. 5 may be or correspond to the photoelectric conversion portion 120 illustrated in FIG. 2.

The transfer transistor TX may be connected between the photoelectric conversion portion PD and a first floating diffusion node FD1. In response to a transfer control signal TS applied to a gate of the transfer transistor TX, the transfer transistor TX may transfer charges generated in the photoelectric conversion portion PD to the first floating diffusion node FD1.

The gain control transistor DCX or MCX may be connected between the first floating diffusion node FD1 and the reset transistor RX. The gain control transistor DCX or MCX may be controlled by a gain control signal DCG or MCG. The gain control transistor DCX or MCX may be a transistor that reduces a conversion gain, which is a rate at which charges are converted into a voltage, by controlling capacitance. In some example embodiments, the gain control transistor DCX or MCX may be included in plural. For example, the gain control transistor DCX or MCX may include a first gain control transistor DCX and a second gain control transistor MCX. The first gain control transistor DCX may be connected between the first floating diffusion node FD1 and a second floating diffusion node FD2, and the second gain control transistor MCX may be connected between the second floating diffusion node FD2 and a third floating diffusion node FD3. According to turn-on or turn-off of the first gain control transistor DCX and the second gain control transistor MCX, the image sensor 10 may operate in a low conversion gain (LCG) mode, a middle conversion gain (MCG) mode, or a high conversion gain (HCG) mode.

The reset transistor RX may be connected between a power voltage line that supplies a power voltage and the third floating diffusion node FD3. When a reset control signal RS is applied to the reset transistor RX, the charges that are accumulated in the third floating diffusion node FD3 may be reset. When the reset control signal RS is applied to the reset transistor RX and the first and/or second gain control transistor DCX and/or MCX is turned on, the charges accumulated in the first floating diffusion node FD1 and/or the second floating diffusion node FD2 may be reset.

However, example embodiments are not limited thereto. For example, the pixel array 10a may include one of the first gain control transistor DCX and the second gain control transistor MCX, and might not include the other of the first gain control transistor DCX and the second gain control transistor MCX. In some example embodiments, the pixel array 10a might not include the gain control transistor DCX or MCX. When the gain control transistor DCX or MCX is not included, an end of the reset transistor RX may be directly connected to the first floating diffusion node FD1.

A gate of the first driving transistor SF1 may be connected to the first floating diffusion node FD1. The first driving transistor SF1 may be a source follower buffer amplifier. The first driving transistor SF1 may perform buffering of a signal according to an amount of charges accumulated in the first floating diffusion node FD1. The first driving transistor SF1 may amplify a potential change at the first floating diffusion node FD1 and output the amplified result to a first output node N1.

The global shutter selection transistor GSX may be connected between the first output node N1 and a second output node N2 and be controlled by a global shutter selection control signal GSEL. In some example embodiments, a first circuit 310a of the photoelectric charge generation circuit 310 may be included in the photoelectric conversion substrate 100, and a second circuit 310b of the photoelectric charge generation circuit 310 may be disposed in the additional wiring portion 200 (e.g., the first additional wiring portion 200a). The global shutter selection transistor GSX may control a signal transmission between the photoelectric conversion substrate 100 and the additional wiring portion 200.

A precharge transistor PCX may precharge the second output node N2 according to a precharge control signal PC. The second precharge selection transistor PSX2 may reset the second output node N2 according to a second precharge selection control signal PSEL2.

The first pixel signal circuit 320 may include a first selection transistor SX1 connected between the first output node N1 and a column line CL. The first selection transistor SX1 may output a first pixel signal VS1 to the column line CL in respond to a first selection control signal SEL1 in a rolling shutter operation.

The sampling circuit 330 may include a first precharge selection transistor PSX1, a sampling transistor SMP1 or SMP2, and a capacitor CT. In some example embodiments, the sampling transistor SMP1 or SMP2 may include a plurality of sampling transistors (e.g., a first sampling transistor SMP1 and a second sampling transistor SMP2), and the capacitor CT may include a plurality of capacitors (e.g., a first capacitor C1 and a second capacitor C2).

The first precharge selection transistor PSX1 may be connected between the second output node N2 and a third output node N3. The first precharge selection transistor PSX1 may be controlled by a first precharge selection control signal PSEL1 and may reset the third output node N3.

The first sampling transistor SMP1 may be connected to the third output node N3 and the first capacitor C1, and may be controlled by a first sampling control signal SMPS1. When the first sampling transistor SMP1 is turned on, charges are accumulated in the first capacitor C1 and sampling of an electrical signal of the third output node N3 may be performed. The second sampling transistor SMP2 may be connected to the third output node N3 and the second capacitor C2, and may be controlled by a second sampling control signal SMPS2. When the second sampling transistor SMP2 is turned on, charges are accumulated in the second capacitor C2 and sampling of an electrical signal of the third output node N3 may be performed.

For example, charges that correspond to the buffered signal based on an amount of charges generated or reset in a plurality of sections included in the global shutter operation may be accumulated in the capacitor CT. For example, the capacitor CT may be or correspond to a memory device configured to perform the global shutter operation.

The second pixel signal circuit 340 may include a second driving transistor SF2 and a second selection transistor SX2.

A gate of the second driving transistor SF2 may be connected to the third output node N3. The second driving transistor SF2 may be a source follower buffer amplifier. The second driving transistor SF2 may perform buffering of a signal according to an amount of charges accumulated in the third output node N3. The second driving transistor SF2 may amplify a potential change at the first floating diffusion node FD1 and output the amplified result. The second selection transistor SX2 may output a second pixel signal VS2 to the column line CL in respond to a second selection control signal SEL2 in a global shutter operation.

In some example embodiments, a part of the plurality of transistors 140 that are included in the photoelectric charge generation circuit 310 and the first pixel signal circuit 320 may be included in the pixel circuit 130. For example, the plurality of transistors 140 that are included in the first circuit 310a of the photoelectric charge generation circuit 310 and the first pixel signal circuit 320 may be included in the pixel circuit 130. The transistors and/or the capacitor CT that is included in the second circuit 310b of the photoelectric charge generation circuit 310, the second sampling circuit 330, and the second pixel signal circuit 340 may be included in the additional wiring portion 200.

More particularly, the transfer transistor TX, the reset transistor RX, the gain control transistor DCX or MCX, and the first driving transistor SF1 that are included in the first circuit 310a of the photoelectric charge generation circuit 310 may be included in the pixel circuit 130. The first selection transistor SX1 that is included in the first pixel signal circuit 320 may be included in the pixel circuit 130. A connection wiring 150 that is electrically connected the doping region (e.g., the floating diffusion region 120f) provided in the substrate 110 and/or the transistor 140 may be included in the pixel circuit 130. An example of the pixel circuit 130 will be described with reference to FIG. 3 and FIG. 4. The following description of the first pixel region PX1 and the second pixel region PX2 may also be applied to the third pixel region PX3 and the fourth pixel region PX4.

In some example embodiments, the first transistor 142 and the second transistor 144 may be included in each pixel region PX. A plurality of second transistors 144 that perform different operations may be shared in the plurality of pixel regions PX that constitute one unit pixel. For example, in the global shutter operation, the first pixel region PX1, the second pixel region PX2, the third pixel region PX3, and the fourth pixel region PX4 illustrated in FIG. 4 may constitute one unit pixel.

In each pixel region PX, the transfer transistor TX may be disposed in a first active region 114a. The transfer transistor TX may include a first gate electrode 142g, which is a vertical transfer gate (VTG) electrode.

The image sensor 10 according to some example embodiments may have a dual vertical transfer gate structure. In the dual vertical transfer gate structure, two transfer transistors TX or two first gate electrodes 142g may be disposed in one first active region 114a. Accordingly, the charges generated in the photoelectric conversion portion 120 may be effectively transferred by the transfer transistor TX. For a clear understanding, in FIG. 4, it is illustrated as an example that two first gate electrodes 142g connected to one first active region 114a are spaced apart from each other, but example embodiments are not limited thereto. In some example embodiments, two first gate electrodes 142g connected to one first active region 114a may be connected to each other in a portion that is adjacent to the first surface 111 of the substrate 110. In some example embodiments, the image sensor 10 may have a single vertical transfer gate structure. In the single vertical transfer gate structure, one transfer transistor TX or one first gate electrode 142g may be disposed in one first active region 114a. Other various modifications are possible.

More particularly, in one pixel region PX, two first transistors 142 or two first gate electrodes 142g may be disposed in the first active region 114a of the first sub-pixel region SP1, two first transistors 142 or two first gate electrodes 142g may be disposed in the first active region 114a of the second sub-pixel region SP2, two first transistors 142 or two first gate electrodes 142g may be disposed in the first active region 114a of the third sub-pixel region SP3, and two first transistors 142 or two first gate electrodes 142g may be disposed in the first active region 114a of the fourth sub-pixel region SP4.

In the second active region 114b that is disposed in the first sub-pixel region SP1 of the first pixel region PX1, a dummy transistor DX may be disposed. In the second active region 114b that is disposed in the second sub-pixel region SP2 of the second pixel region PX2, a dummy transistor DX may be disposed. For example, the dummy transistor DX might not act as a transistor and enhance a structural stability. In some example embodiments, the dummy transistor DX may perform any of various acts.

In each of the second active region 114b that is disposed in the third sub-pixel region SP3 of the first pixel region PX1 and the second active region 114b that is disposed in the fourth sub-pixel region SP4 of the first pixel region PX1, the first gain control transistor DCX and the second gain control transistor MCX may be disposed. In the second active region 114b that is disposed in the fourth sub-pixel region SP4 of the second pixel region PX2, the reset transistor RX may be disposed.

In the second active region 114b that is disposed in the second sub-pixel region SP2 of the first pixel region PX1 and the second active region 114b that is disposed in the first sub-pixel region SP1 of the second pixel region PX2, one first driving transistor SF1 may be shared. In the second active region 114b that is disposed in the third sub-pixel region SP3 of the second pixel region PX2 and the second active, the first selection transistor SX1 may be disposed.

For example, the ground region may be disposed in the second active region 114b that is disposed in the first sub-pixel region SP1 of the first pixel region PX1 and the ground region may be disposed in the second active region 114b that is disposed in the second sub-pixel region SP2 of the second pixel region PX2. However, example embodiments are not limited thereto, and a position of the ground region may be variously modified.

Structures of the plurality of transistors 140 will be described in detail with reference to FIG. 2 to FIG. 5.

In some example embodiments, the transfer transistor TX may be or correspond to the first transistor 142 that includes a first gate electrode 142g of a vertical transfer gate electrode. The reset transistor RX, the first gain control transistor DCX, the second gain control transistor MCX, the first selection transistor SX1, the dummy transistor DX, and the first driving transistor SF1 may be or correspond to the second transistor 144 that includes a second gate electrode 144g. The second gate electrode 144g has a structure, a shape, or a depth different from a structure, a shape, or a depth of the first gate electrode 142g.

For example, the second transistor 144 may include a third transistor 146 and a fourth transistor 148. A gate insulation layer 140i of the third transistor 146 may be different from a gate insulation layer 140i of the fourth transistor 148. The third transistor 146 may include a first gate insulation layer 142i, and the fourth transistor 148 may include a second gate insulation layer 144i that has a thickness different from a thickness of the first gate insulation layer 142i. The gate insulation layer 140i that is included in each of the first transistor 142 and the third transistor 146 may be or correspond to the first gate insulation layer 142i, and the second gate insulation layer 144i may have a thickness less than a thickness of the first gate insulation layer 142i.

In some example embodiments, the reset transistor RX, the first gain control transistor DCX, the second gain control transistor MCX, and the first selection transistor SX1 may be or correspond to the third transistor 146, and the first driving transistor SF1 may be or correspond to the fourth transistor 148. The dummy transistor DX may be or correspond to the third transistor 146 or the fourth transistor 148 depending to a role.

In some example embodiments, the first transistor 142 may include the first gate electrode 142g that is electrically connected to the photoelectric conversion portion 120. The first gate electrode 142g of the vertical transfer gate electrode may have a cross-sectional shape having a length or a depth greater than a width. The width may refer to a width of the first gate electrode 142g in a plan view, for example, a minimum width in the X-axis or Y-axis direction in the drawings. The length may be a length (e.g., a maximum length) or a depth (e.g., a maximum depth) of the first gate electrode 142g in the thickness direction of the image sensor 10 (the Z-axis direction in the drawings). The first transistor 142 may further include the gate insulation layer 140i (e.g., the first gate insulation layer 142i) that is disposed between the first gate electrode 142g and the substrate 110 (e.g., the semiconductor substrate 110a).

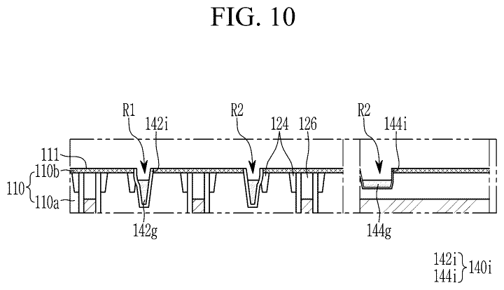

The first transistor 142 may further include a first insulation layer 142j that is disposed on a first surface of the first gate electrode 142g at a side of the first surface 111 of the substrate 110. The first insulation layer 142j may be formed by etching a partial portion of the first gate electrode 142g in a first recess R1 (refer to FIG. 10) and filling an insulating material in the etched portion. By the first insulation layer 142j, a gate induced drain leakage (GIDL) may be reduced.

The first gate electrode 142g and/or the first insulation layer 142j of the first transistor 142 may have a buried structure. That is, at least a partial portion of the first gate electrode 142g and/or the first insulation layer 142j may be buried inside the substrate 110. For example, the first surface of the first gate electrode 142g at the side of the first surface 111 of the substrate 110 may be disposed inside the substrate 110 and be disposed on a different plane from the first surface 111 of the substrate 110. A second surface of the first insulation layer 142j at a side of the second surface 112 of the substrate 110 may be disposed inside the substrate 110, and a first surface of the first insulation layer 142j at the side of the first surface 111 of the substrate 110 may be disposed on the same plane as the first surface 111 of the substrate 110 or inside the substrate 110. However, example embodiments are not limited thereto. The first surface of the first insulation layer 142j may be disposed to protrude than the first surface 111 of the substrate 110.

The first insulation layer 142j may include or be formed of an insulating material. For example, the first insulation layer 142j may include or be formed of silicon oxide, silicon nitride, silicon oxynitride, and/or a low dielectric constant material. The low dielectric constant material may be a material having a dielectric constant lower than a dielectric constant of silicon oxide. However, example embodiments are not limited thereto. The first insulation layer 142j may include or be formed of any of various insulating materials.

In some example embodiments, the second transistor 144 may have a structure, a shape, or a depth different from a structure, a shape, or a depth of the first transistor 142. Having a different structure, shape, or depth may mean that an electrode, a layer, or a doped portion that is included in or related to one of the first and second transistors 142 and 144 is not included in or related to another one of the first and second transistors 142 and 144. Having a different structure, shape, or depth may mean that a position, an arrangement, or the like of electrodes, layers, or doped portions that are included in or related to the first and second transistors 142 and 144 are different. Having a different structure or shape may mean that cross-sectional structures or shapes of electrodes, layers, or doped portions that are included in or related to the first and second transistors 142 and 144 are different. Having a different depth may mean that depths of electrodes, layers, or doped portions that are included in or related to the first and second transistors 142 and 144 are different or depth of the first and second transistors 142 and 144 are different. That is, even when there is a difference in width or length in a plan view, planar shape, or the like, the transistors may be regarded as the same structure or shape.

The second transistor 144 may include the second gate electrode 144g, and a source region 144s (refer to FIG. 6 and FIG. 7) and a drain region 144d (refer to FIG. 6 and FIG. 7). The source region 144s and the drain region 144d may be disposed in the substrate 110 (e.g., the semiconductor substrate 110a) at both sides of the second gate electrode 144g. The second transistor 144 may further include the gate insulation layer 140i (e.g., the first gate insulation layer 142i or the second gate insulation layer 144i) that is disposed between the second gate electrode 144g and the substrate 110.

The plurality of second gate electrodes 144g that are included in the plurality of second transistors 144g of the plurality of pixel regions PX may have the same cross-sectional structure or shape. Having the same cross-sectional structure or shape may mean that an electrode, a layer or a doped portion that is included in or related to one of the plurality of second gate electrodes 144g is included in or related to another one of the plurality of gate electrodes 144g. Having the same cross-sectional structure or shape may mean that a position, an arrangement, or the like of electrodes, layers, or doped portions that are included in or related to the plurality of second gate electrodes 144g are the same. Having the same cross-sectional structure or shape may mean that cross-sectional structures or shapes of electrodes, layers, or doped portions that are included in or related to the plurality of second gate electrodes 144g are the same. That is, even when there is a difference in width or length in a plan view, planar shape, or the like, the transistors or the second gate electrodes 144g may be regarded as having the same cross-sectional structure or shape.

In some example embodiments, a second depth H2 of the second transistor 144 may be less than a first depth H1 of the first transistor 142. The first depth H1 may refer to a distance (e.g., a minimum distance) between the second surface of the first gate electrode 142g at the side of the second surface 112 of the substrate 110 and the first surface 111 of the substrate 110. The second depth H2 may refer to a distance (e.g., a minimum distance) between the second surface of the second gate electrode 144g at the side of the second surface 112 of the substrate 110 and the first surface 111 of the substrate 110. Accordingly, the first transistor 142 and the plurality of second transistors 144 may more stably perform different roles. For example, second depths H2 of the plurality of second transistors 144 may be the same. In some example embodiments, second depths H2 of at least two second transistors 144 of the plurality of second transistors 144 may be different from each other.

In FIG. 4, it is illustrated as an example that the second surface of the first gate electrode 142g and the second surface of the second gate electrode 144g at the side of the second surface 112 of the substrate 110 have the same or similar shapes. However, example embodiments are not limited thereto. The second surface of the first gate electrode 142g and the second surface of the second gate electrode 144g at the side of the second surface 112 of the substrate 110 may have different shapes. For example, the second transistor 144 may have a three-dimensional (3D) transistor having a three-dimensional structure or the second gate electrode 144g may have a three-dimensional (3D) gate electrode having a three dimensional structure. For example, in a cross-sectional view, the second transistor 144 or the second gate electrode 144g may have a depth change portion in which a depth is changed in an inner portion between both side portions. Accordingly, a transistor width of the second transistor 144 may increase and an area of the second transistor 144 may be reduced.

In some example embodiments, the second transistor 144 may further include a second insulation layer 144j that is disposed on a first surface of the second gate electrode 144g at a side of the first surface 111 of the substrate 110. The second insulation layer 144j may be formed by etching a partial portion of the second gate electrode 144g in a first recess R2 (refer to FIG. 10) and filling an insulating material in the etched portion. By the second insulation layer 144j, a gate induced drain leakage may be reduced.

The second gate electrode 144g and/or the second insulation layer 144j of the second transistor 144 may have a buried structure. That is, at least a partial portion of the second gate electrode 144g and/or the second insulation layer 144j may be buried inside the substrate 110. For example, the first surface of the second gate electrode 144g at the side of the first surface 111 of the substrate 110 may be disposed inside the substrate 110 and be disposed on a different plane from the first surface 111 of the substrate 110. A second surface of the second insulation layer 144j at a side of the second surface 112 of the substrate 110 may be disposed inside the substrate 110, and a first surface of the second insulation layer 144j at the side of the first surface 111 of the substrate 110 may be disposed on the same plane as the first surface 111 of the substrate 110 or inside the substrate 110. However, example embodiments are not limited thereto. The first surface of the second insulation layer 144j may be disposed to protrude than the first surface 111 of the substrate 110.

The second insulation layer 144j may include or be formed of an insulating material. For example, the second insulation layer 144j may include or be formed of silicon oxide, silicon nitride, silicon oxynitride, and/or a low dielectric constant material. However, example embodiments are not limited thereto. The second insulation layer 144j may include or be formed of any of various insulating materials.

In a plan view, the second gate electrode 144g of the second transistor 144 may include a portion that overlaps a central portion of the second active region 114b. For example, the second gate electrode 144g of the second transistor 144 may extend in a direction that is inclined to the first direction (the Y-axis direction in the drawings) and the second direction (the X-axis direction in the drawings). Accordingly, in both portions of the second active region 114b, the source region 144s and the drain region 144d of the second transistor 144 and a plurality of first contact vias 172 that are connected thereto may be stably formed. A voltage configured to operate the second transistor 144 may be applied to the source region 144s and the drain region 144d of the second transistor 144 through the plurality of first contact vias 172. In some example embodiments, the plurality of first contact vias 172 may be connected to the same node. For example, in FIG. 4, the second active region 114b in the second sub-pixel region SP2 or the first pixel region PX1, the second active region 114b in the first sub-pixel region SP1 of the second pixel region PX2, and the second active region 114b in the third sub-pixel region SP3 of the second pixel region PX2 may be connected to the same node. This may be for implementing an electoral connection according to a circuit diagram illustrated in FIG. 4, and various voltages may be applied to the plurality of first contact vias 172 depending on an operation or a circuit of the image sensor 10.

In some example embodiments, the plurality of transistors 140 may have a buried structure and accordingly may be easily formed. For example, the transistor 140 might not include a spacer or the like and a process of forming the spacer or the like may be omitted.

Further, the plurality of transistors 140 may have the buried structure and accordingly the plurality of transistors 140 (e.g., the plurality of second transistors 144) that perform various roles may be easily formed. For example, by adjusting an etching depth, an arrangement of the source region 144s and the drain region 144d, or the like, a channel length may be adjusted and accordingly the plurality of transistors 140 (e.g., the plurality of second transistors 144) that perform various roles may be easily formed. Accordingly, the plurality of transistors 140 (e.g., the plurality of second transistors 144) that are included in the image sensor 10 of the hybrid global shutter structure and perform various roles may be easily formed. Referring to FIG. 6 and FIG. 7 together with FIG. 4, various examples of the second transistors 144 will be described in detail.

FIG. 6 is a rear perspective view that conceptually illustrates the reset transistor RX illustrated in FIG. 4 and first contact vias 172 connected to the reset transistor RX. In FIG. 6, a structure of the reset transistor RX is conceptually illustrated to describe an electrical connection structure of the reset transistor RX. That is, planar shapes of the second active region 114b and the reset transistor RX illustrated in FIG. 6 may be different from planar shapes of the second active region 114b and the reset transistor RX illustrated in FIG. 4. The electrical connection structure of the reset transistor RX illustrated in FIG. 6 may be the same as an electrical connection structure of the reset transistor RX illustrated in FIG. 4, and an arrangement of the second gate electrode 144g and the second insulation layer 144j illustrated in FIG. 6 may be or correspond to an arrangement of the second gate electrode 144g and the second insulation layer 144j of the second transistor 144 illustrated in FIG. 3.

Referring to FIG. 4 and FIG. 6, the reset transistor RX according to some example embodiments may include a second gate electrode 144g and a second insulation layer 144j. The second gate electrode 144g may have a buried structure and overlap the second active region 114b in a plan view. The second insulation layer 144j may have a buried structure and be disposed on the second gate electrode 144g. The second insulation layer 144j of the reset transistor RX may be disposed in substantially the same position as the second gate electrode 144g of the reset transistor RX and may have substantially the same planar shape as the second gate electrode 144g of the reset transistor RX.

In the second active region 114b, a source region 144s may be disposed at one side of the second gate electrode 144g, and a drain region 144d may be disposed at the other side of the second gate electrode 144g. First contact vias 172 that are electrically connected to the reset transistor RX may include a gate contact via 172g that is electrically connected to the second gate electrode 144g, a source contact via 172s that is electrically connected to the source region 144s, and a drain contact via 172d that is electrically connected to the drain region 144d.

In the description referring to FIG. 6, the reset transistor RX is described as an example. The description referring to FIG. 6 may be applied to the third transistor 146. That is, the description referring to FIG. 6 may be applied to the reset transistor RX, the gain control transistor DCX or MCX, the first selection transistor SX1, and/or the dummy transistor DX that corresponds to the third transistor 146.

FIG. 7 is a rear perspective view that conceptually illustrates the first driving transistor SF1 illustrated in FIG. 4 and first contact vias connected to the first driving transistor SF1. In FIG. 7, a structure of the first driving transistor SF1 is conceptually illustrated to describe an electrical connection structure of the first driving transistor SF1. That is, planar shapes of the second active region 114b and the first driving transistor SF1 illustrated in FIG. 7 may be different from planar shapes of the second active region 114b and the first driving transistor SF1 illustrated in FIG. 4. The electrical connection structure of the first driving transistor SF1 illustrated in FIG. 7 may be the same as an electrical connection structure of the first driving transistor SF1 illustrated in FIG. 4, and an arrangement of the second gate electrode 144g and the second insulation layer 144j illustrated in FIG. 7 may be or correspond to an arrangement of the second gate electrode 144g and the second insulation layer 144j of the second transistor 144 illustrated in FIG. 3.

Referring to FIG. 4 and FIG. 7, the first driving transistor SF1 may be shared in the second sub-pixel region SP2 of the first pixel region PX1 and the first sub-pixel region SP1 of the second pixel region PX2.

More particularly, the second gate electrode 144g of the first driving transistor SF1 may include a first gate portion 144p, a second gate portion 144q, and a third gate portion 144r. In a plan view, the first gate portion 144p may overlap a central portion of the second active region 114b that is disposed in the second sub-pixel region SP2 of the first pixel region PX1. For example, the first gate portion 144p may extend in a direction (e.g., a first diagonal direction) that is inclined to the first direction (the Y-axis direction in the drawings) and the second direction (the X-axis direction in the drawings). In a plan view, the second gate portion 144q may overlap a central portion of the second active region 114b that is disposed in the first sub-pixel region SP1 of the second pixel region PX2. For example, the second gate portion 144q may extend in a direction (e.g., a second diagonal direction) that is inclined to the first direction (the Y-axis direction in the drawings) and the second direction (the X-axis direction in the drawings) and crosses (e.g. is perpendicular to) the first diagonal direction. In a plan view, the third gate portion 144r may connect the first gate portion 144p and the second gate portion 144q. For example, the third gate portion 144r may extend in the first direction (the Y-axis direction in the drawings) and connect the first gate portion 144p and the second gate portion 144q.

As in the above, the second insulation layer 144j may be disposed on the first surface of the second gate electrode 144g of the first driving transistor SF1 to have a buried structure. In a plan view, the second insulation layer 144j of the first driving transistor SF1 may overlap the second gate electrode 144g of the first driving transistor SF1. For example, the second insulation layer 144j of the first driving transistor SF1 may be disposed in substantially the same position as the second gate electrode 144g of the first driving transistor SF1 and may have substantially the same planar shape as the second gate electrode 144g of the first driving transistor SF1. For example, the second insulation layer 144j of the first driving transistor SF1 may include a first insulation portion 144x on the first gate portion 144p, a second insulation portion 144y on the second gate portion 144q, and a third insulation portion 144z on the third gate portion 144r.

In some example embodiments, a drain region 144d may be disposed between the first gate portion 144p and the second gate portion 144q in the first direction (the Y-axis direction in the drawings), and source regions 144s may be disposed at each of an outer side of the first gate portions 144p and an outer side of the second gate portions 144q. First contact vias 172 that are electrically connected to the first driving transistor SF1 may include one drain contact via 172d that is electrically connected to one drain region 144d, and two source contact vias 172s that are electrically connected to two source regions 144s and 144d at the both outer sides of the first and second gate portions 144p and 144q, respectively. When the first driving transistor SF1 shares the drain region 144d as in the above, a transistor width may increase and performance may be enhanced.

In some example embodiments, by the connection wiring 150, a first gate contact via that is electrically connected to the second gate electrode 144g (more particularly, the third gate portion 144r) may be omitted. Accordingly, in FIG. 7, the first gate contact via is omitted. However, example embodiments are not limited thereto. In some example embodiments, the first gate contact via may be further included.

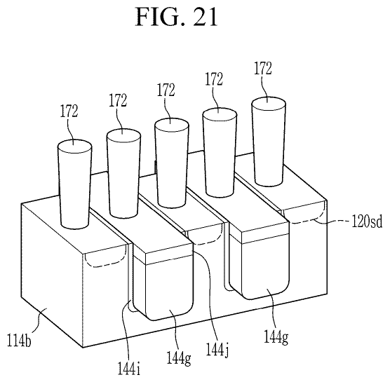

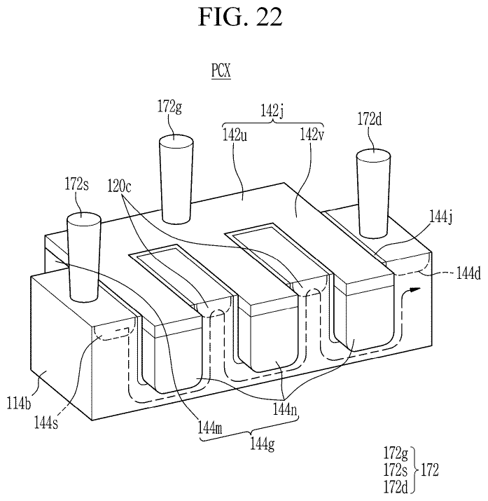

Example embodiments are not limited to a shape, an arrangement, or the like of the second gate electrode 144g, the source region 144s, and the drain region 144d, the first contact via 172 of the first driving transistor SF1. Various modifications are possible. Examples of a second transistor 144 that performs various roles will be described with referent to FIG. 21 and FIG. 22.

Referring to FIG. 2 to FIG. 5 again, in some example embodiments, a connection wiring 150 that is electrically connected the doping region (e.g., the floating diffusion region 120f) and/or the transistor 140 and has a buried structure may be further included. The connection wiring 150 may refer to a portion that electrically connect a plurality of doping regions, refer to a portion that electrically connect a doping region and a transistor 140, or refer to a portion that electrically connect a plurality of transistors 140, or the like.

For example, the connection wiring 150 may include a portion that electrically connects the floating diffusion region 120f of the first pixel region PX1 and the first driving transistor SF1 and/or a portion that electrically connects the floating diffusion region 120f of the second pixel region PX2 and the first driving transistor SF1. The connection wiring 150 may constitute at least a partial portion of the first floating diffusion node FD1 illustrated in FIG. 5.

In some example embodiments, in the first active region 114a of the sub-pixel region SP, the floating diffusion region 120f may be disposed to be adjacent to a central portion of the pixel region PX. Accordingly, the floating diffusion regions 120f that are provided in the plurality of sub-pixel regions SP of each pixel region PX may be disposed to be adjacent to a central portion of each pixel region PX.

In some example embodiments, the connection wiring 150 may include a first connection portion 152, a second connection portion 154, and a third connection portion 156.

In the first pixel region PX1, the first connection portion 152 may be disposed at a central portion of the first pixel region PX1, and may be electrically connected to the plurality of floating diffusion regions 120f (e.g., a plurality of first floating diffusion regions) that are adjacent to the central portion of the first pixel region PX1. In a plan view, the first connection portion 152 may overlap the plurality of floating diffusion regions 120f that are adjacent to the central portion of the first pixel region PX1. Accordingly, the first connection portion 152 may be easily connected to the plurality of floating diffusion regions 120f provided in the first pixel region PX1. A partial portion of the first connection portion 152 may be disposed on a partial portion of the first inner isolation portion 126c and/or the second inner isolation portion 126d.

In the second pixel region PX2, the second connection portion 154 may be disposed at a central portion of the second pixel region PX2, and may be electrically connected to the plurality of floating diffusion regions 120f (e.g., a plurality of second floating diffusion regions) that are adjacent to the central portion of the second pixel region PX2. In a plan view, the second connection portion 154 may overlap the plurality of floating diffusion regions 120f that are adjacent to the central portion of the second pixel region PX2. Accordingly, the second connection portion 154 may be easily connected to the plurality of floating diffusion regions 120f provided in the second pixel region PX2. A partial portion of the second connection portion 154 may be disposed on a partial portion of the first inner isolation portion 126c and/or the second inner isolation portion 126d.

The third connection portion 156 may include a first extension portion 156a and a second extension portion 156b. The first extension portion 156a may electrically connect (e.g., directly connect) the first connection portion 152 and the second connection portion 154. The second extension portion 156b may electrically connect (e.g., directly connect) the first extension portion 156a and the first driving transistor SF1 (e.g., the second gate electrode 144g of the first driving transistor SF1). The third connection portion 156 may include a third extension portion 156c that electrically connects (e.g., directly connects) the first extension portion 156a and the second active region 114b in the fourth sub-pixel region SP4 of the first pixel region PX1. In some example embodiments, the first extension portion 156a and the second extension portion 156b may be disposed on the device isolation portion 124 and the isolation portion 126 to hinder or prevent an unwanted electrical connection.

The first extension portion 156a may longitudinally extend in the first direction (the Y-axis direction in the drawings), and the second extension portion 156b may longitudinally extend in the second direction (the X-axis direction in the drawings). Accordingly, a structure of the third connection portion 156 may be simplified. However, example embodiments are not limited thereto. A shape, an arrangement, or the like of the first extension portion 156a, the second extension portion 156b, the third extension portion 156c, or the third connection portion 156 may be variously modified.

A partial portion of the third connection portion 156 may be disposed on a partial portion of the first inner isolation portion 126c and/or the second inner isolation portion 126d.

In some example embodiments, the connection wiring 150 may electrically connect the floating diffusion region 120f of the first pixel region PX1 and/or the second pixel region PX2 and the first driving transistor SF1 in a plan view. That is, the connection wiring 150 having the buried structure may extend in a plan view to connect the floating diffusion region 120f that is disposed inside the substrate 110 and the first driving transistor SF1 that has the buried structure buried inside the substrate 110. In the thickness direction of the image sensor 10 (the Z-axis direction in the drawings), the connection wiring 150 may be disposed at a position where the floating diffusion region 120f and the first driving transistor SF1 are disposed. Accordingly, a portion (e.g., the first contact via 172 and the first wiring layer 174) that is disposed at a position where the floating diffusion region 120f and the first driving transistor SF1 are not disposed in the thickness direction of the image sensor 10 might not be included for an electrical connection of the floating diffusion region 120f and the first driving transistor SF1.

In some example embodiments, the connection wiring 150 may directly connect the floating diffusion region 120f of the first pixel region PX1 and/or the second pixel region PX2 to the first driving transistor SF1 without an additional wiring (e.g. without going through the wiring portion 170, more particularly, without going through the first contact via 172 and/or the first wiring layer 174). Accordingly, a plurality of first contact vias that are connected to the plurality of floating diffusion regions 120f, a first contact via that is electrically connected to the second gate electrode 144g of the first driving transistor SF1, a first contact via that is electrically connected to the third extension portion 156c, and a wiring portion of the first wiring layer 174 that connects the first contact vias may be omitted. In an example illustrated in FIG. 4, eight first contact vias that are connected to eight floating diffusion regions 120f provided in the first pixel region PX1 and the second pixel region PX2, one first contact via that is electrically connected to the second gate electrode 144g of the first driving transistor SF1, and one first contact via that is electrically connected to the third extension portion 156c may be omitted. That is, total ten first contact vias may be omitted. Further, a wiring portion of the first wiring layer 174 that extends in a plan view to be connected to the ten first contact vias may be omitted.

Accordingly, a leakage current may be reduced. Particularly, in the global shutter structure (e.g., the hybrid global shutter structure), time from reset to signal sampling may be long and a leakage current at the floating diffusion region 120f may be large, and deterioration due to differences in the pixel circuits 130 caused by a process error may be large. By the connection wiring 150 according to example embodiments, the leakage current in the global shutter structure may be effectively reduced.

Further, parasitic capacitance between the plurality of first contact vias, and parasitic capacitance between the floating diffusion region 120f and the wiring portion of the first wiring layer 174 may be reduced. Accordingly, a conversion gain of the image sensor 10 may be enhanced and efficiency of the image sensor 10 may be enhanced. The wiring portion 170 (e.g., the first wiring layer 174) may be freely disposed.

The connection wiring 150 is disposed to cross the first pixel region PX1 and the second pixel region PX2, and the plurality of floating diffusion regions 120f provided in the first pixel region PX1 and the second pixel region PX2 may be electrically connected to the first driving transistor SF1 that is shared in the first pixel region PX1 and the second pixel region PX2. When the connection wiring 150 is shared in at least two pixel regions PX, a structure of the connection pattern 150 and a structure of the wiring portion 170 may be simplified. For example, a number of the first contact vias 172 may be reduced and an interval between the first contact vias 172 may increase.

In some example embodiments, the first gate electrode 142g, the second gate electrode 144g, and/or the connection wiring 150 may be a buried pattern that has a buried structure that is buried inside the substrate 110. The first gate insulation layer 142i or the second gate insulation layer 144i that is disposed at a lower portion of the first gate electrode 142g or the second gate electrode 144g may be a buried pattern that has a buried structure that is buried inside the substrate 110. The first insulation layer 142j or the second insulation layer 144j that is disposed on the first gate electrode 142g or the second gate electrode 144g may be a buried pattern that has a buried structure that is buried inside the substrate 110. That is, the image sensor 10 may include a plurality of buried patterns that include the first gate electrode 142g, the second gate electrode 144g, the first insulation layer 142j, the second insulation layer 144j, the first gate insulation layer 142i, the second gate insulation layer 144i, and/or the connection wiring 150.

For example, the first transistor 142, the second transistor 144, the third transistor 146, the fourth transistor 148, the transfer transistor TX, the reset transistor RX, the gain control transistor DCX or MCX, the first selection transistor SX1, the first driving transistor SF1, the dummy transistor DX, or the like may be referred to as a buried transistor or a buried channel transistor. The first gate electrode 142g and/or the second gate electrode 144g may be referred to as a buried gate electrode. The connection wiring 150 may be referred to as a buried connection wiring or a buried local interconnector. The first gate electrode 142g, the second gate electrode 144g, and/or the connection wiring 150 may include or be formed of a semiconductor material, and the first gate electrode 142g, the second gate electrode 144g, and/or the connection wiring 150 may be referred to a buried semiconductor pattern. For example, the buried structure of the connection wiring 150 and the plurality of transistors 140 may be referred to as a buried poly interconnection and channel (BPIC) structure. The first insulation layer 142j or the second insulation layer 144j may be referred to as a buried insulation layer, a buried insulation pattern, or the like, and the first gate insulation layer 142i or the second gate insulation layer 144i may be referred to as a buried gate insulation layer or the like.

The buried structure that is buried inside the substrate 110 may refer to a structure in which at least a partial portion is disposed between the first surface 111 and the second surface 112 of the substrate 110. For example, the buried structure that is buried inside the substrate 110 may refer to a structure that includes only a portion disposed between the first surface 111 and the second surface 112 of the substrate 110 and/or a portion the same as the first surface 111 of the substrate 110, and not includes a portion outside the first surface 111 of the substrate 110 or a portion protruding from the first surface 111 of the substrate 110 to the wiring portion 170.

In some example embodiments, each of the gate electrodes 140g that are included in the plurality of transistors 140 and the connection wiring 150 may have a buried structure. Accordingly, the active region 114 may be sufficiently secured and a large number of the transistors 140 may be disposed in the pixel region PX. Accordingly, problems such as, for example, a short channel effect and/or issues that may be related to, for example, an insufficient active area may be reduced or prevented. Since each of the gate electrodes 140g that are included in the plurality of transistors 140 and the connection wiring 150 may have the buried structure, a portion on the first surface 111 of the substrate 110 might not be included and a thickness of the first interlayer insulation layer 172i may be reduced. Accordingly, a height of the first contact via 172 may be reduced and electrical resistance of the first contact via 172 may be reduced. On the other hand, in Comparative Example in which at least a partial portion of a plurality of transistors and/or a connection wiring is disposed on a first surface of the substrate, a first interlayer insulation layer may have a relatively large thickness to insulate the plurality of transistors and the first wiring layer.

In some example embodiments, the plurality of transistors 140, each having the buried structure, may be formed by the same process, and the connection wiring 150 having the buried structure may be formed.

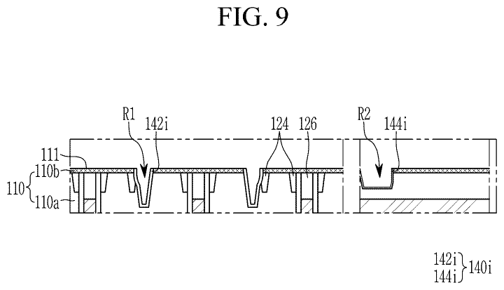

The phrase the plurality of transistors 140 are formed by the same process may refer that the plurality of gate electrodes 140g (e.g., the first gate electrode 142g and the second gate electrode 144g), each having the buried structure, are formed by performing a removing process of removing a portion of a first buried layer on the surface insulation layer 110b. Before the removing process, the first buried layer may include portions, each filling a plurality of recesses (e.g., a first recess R1 (refer to FIG. 9) and a second recess R2 (refer to FIG. 9)) and the portion on the surface insulation layer 110b. For example, when each of the plurality of gate electrodes 140g have the buried structure by the same removing process, for example, the same chemical mechanical polishing (CMP), the plurality of gate electrodes 140g may be regarded to be formed by the same process. For example, the plurality of gate electrodes 140g may have the buried structure by one chemical mechanical polishing process performed at the first surface 111 of the substrate 110. For example, when the plurality of gate electrodes 140, each having the buried structure, are formed, partial portions the plurality of gate electrodes 140 are removed, and the first insulation layer 142j and the second insulation layer 144j are formed together, the plurality of transistors 140 may be regarded to be formed by the same process.

In some example embodiments, the first gate electrode 142g and the second gate electrode 144g of the plurality of transistors 140 may include or be formed of the same base material. The base material may refer to a material of the largest amount. That is, including the same base material may include a case where the same material is included, a case where the same material is included but there is a difference in the composition, and a case where there is a difference in presence or absence of doping, conductivity type, doping concentration, dopant material, or the like. For example, when the first gate electrode 142g and the second gate electrode 144g of the plurality of transistors 140 include the same semiconductor material and there is a difference in presence or absence of doping, conductivity type, doping concentration, dopant material, or the like, the first gate electrode 142g and the second gate electrode 144g of the plurality of transistors 140 may be regarded to include the same base material.

In some example embodiments, the first gate electrode 142g and the second gate electrode 144g of the plurality of transistors 140 may include or be formed of the same base material (e.g., the same semiconductor material). For example, the first gate electrode 142g and the second gate electrode 144g of the plurality of transistors 140 may include or be formed of a polycrystalline semiconductor material (e.g., polycrystalline silicon) as the base material.

In some example embodiments, the connection wiring 150 may include or be formed of, for example, a polycrystalline semiconductor material (e.g., polycrystalline silicon) as a base material, but example embodiments are not limited thereto. For example, the connection wiring 150 may include or be formed of a semiconductor material (e.g., a polycrystalline semiconductor material, as an example, polycrystalline silicon) as the base material that is the same as the base material of the first gate electrode 142g and the second gate electrode 144g.

When the first gate electrode 142g, the second gate electrode 144g, and/or the connection wiring 150 includes the semiconductor material, the first gate electrode 142g, the second gate electrode 144g, and/or the connection wiring 150 may be easily formed and have a desirable conductivity type and/or electrical conductivity depending on presence or absence of doping and/or a doping concentration. However, example embodiments are not limited thereto. The first gate electrode 142g, the second gate electrode 144g, and/or the connection wiring 150 may include or be formed of a material other than the semiconductor material as the base material.

In some example embodiments, in the plurality of transistors 140 and the connection wiring 150, there may be a difference in presence or absence of the gate insulation layer 140i or thickness of the gate insulation layer 140i. Even when each of the plurality of transistors 140 and the connection wiring 150 has the buried structure, there may be the difference in presence or absence of the gate insulation layer 140i or thickness of the gate insulation layer 140i in consideration of properties of the transistors 140 and the connection wiring 150 that perform different operations or roles. For example, a thickness of the first gate insulation layer 142i that is included in the first transistor 142 or the third transistor 146 may be greater than a thickness of the second gate insulation layer 144i that is included in the fourth transistor 148, and the connection wiring 150 might not include the gate insulation layer 140i for an ohmic contact.

In some example embodiments, in the plurality of transistors 140 and the connection wiring 150, each having the buried structure, there may be a difference in presence or absence of the first or second insulation layer 142j or 144j. For example, the transistor 140 may include the first or second insulation layer 142j or 144j to reduce a gate induced drain leakage current, and the connection wiring 150 might not include the first or second insulation layer 142j or 144j. Accordingly, the first surface of the first gate electrode 142g or the first surface of the second gate electrode 144g at the side of the first surface 111 of the substrate 110 may be disposed inside the substrate, rather than a first surface of the connection wiring 150 being disposed inside the substrate at the side of the first surface 111 of the substrate 110. For example, a distance between the first surface of the first gate electrode 142g and the first surface 111 of the substrate 110 or a distance between the first surface of the second gate electrode 144g and the first surface 111 of the substrate 110 is greater than a distance between the first surface of the connection wiring 150 and the first surface 111 of the substrate 110.

In some example embodiments, the first insulation layer 142j and the second insulation layer 144j may have substantially the same thickness. Substantially the same thickness may refer to have a thickness difference due to process error (e.g., a thickness difference less than 10%).

For example, a thickness of the first insulation layer 142j may be the same or greater than a thickness of the first gate electrode 142g. Accordingly, the thickness of the first insulation layer 142j may be sufficiently secured and the gate induced drain leakage current may be effectively reduced. In some example embodiments, a thickness of the first gate electrode 142g may be greater than a thickness of the first insulation layer 142j. Accordingly, a process margin of the first contact via 172 that is connected to the first gate electrode 142g may be secured.

For example, a thickness of the second insulation layer 144j may be the same or greater than a thickness of the second gate electrode 144g. Accordingly, the thickness of the second insulation layer 144j may be sufficiently secured and the gate induced drain leakage current may be effectively reduced. In some example embodiments, a thickness of the second gate electrode 144g may be greater than a thickness of the second insulation layer 144j. Thereby, a process margin of the first contact via 172 that is connected to the second gate electrode 144g may be secured or sufficiently so.

A depth H of the connection wiring 150 may be less than the first depth H1 of the first transistor 142 or the second depth H2 of the second transistor 144. The depth H of the connection wiring 150 refer to a distance (e.g., a minimum distance) between a second surface of the connection wiring 150 at the second surface 112 of the substrate 110 and the first surface 111 of the substrate 110. This may be because the first or the second insulation layer 142j or 144j is not disposed on the connection wiring 150 and the connection wiring 150 has an extended shape in a plan view to have a relatively large planar area. However, example embodiments are not limited thereto. The depth H of the connection wiring 150 may be the same as or greater than the first depth H1 of the first transistor 142 or the second depth H2 of the second transistor 144.

The depth H or a thickness of the connection wiring 150 may be greater than a thickness of the first insulation layer 142j or the second insulation layer 144j. Accordingly, the connection wiring 150 may be stably connected to the first gate electrode 142g or the second gate electrode 144g (e.g. the second gate electrode 144g) that is disposed at a lower portion of the first insulation layer 142j or the second insulation layer 144j (e.g. the second insulation layer 144j). However, example embodiments are not limited thereto.

Accordingly, the first gate electrode 142g, the second gate electrode 144g, and the connection wiring 150 may have three or more structures that have a difference in presence or absence of the gate insulation layer 140i, thickness of the gate insulation layer 140i, or presence or absence of the first or second insulation layer 142j or 144j. A manufacturing method of the first gate electrode 142g, the second gate electrode 144g, and the connection wiring 150 will be described in more detail in a manufacturing method of the image sensor 10.

The pixel circuit 130 may be an example, but example embodiments are not limited thereto. Accordingly, the pixel circuit 130 may have any of various structures or arrangements.

In some example embodiments, the plurality of transistors and the capacitor CT that are included in the second circuit 310b of the photoelectric charge generation circuit 310, the sampling circuit 330, and the second pixel signal circuit 340 may be included in the additional wiring portion 200 (e.g., the first additional wiring portion 200a). For example, the global shutter selection transistor GSX, the precharge transistor PCX, the second precharge selection transistor PSX2, the first precharge selection transistor PSX1, the sampling transistor SMP1 or SMP2, the capacitor CT, the second driving transistor SF2, and the second selection transistor SX2 may be included in the additional wiring portion 200 (e.g., the first additional wiring portion 200a). However, example embodiments are not limited thereto. A shape, a position, an arrangement, or the like of the plurality of transistors and the capacitor CT that are included in the additional wiring portion 200 (e.g., the first additional wiring portion 200a) may be variously modified.

In FIG. 2, it is illustrated as an example that the capacitor CT is included in the first additional wiring portion 200a. The capacitor CT may constitute the memory device that is electrically connected to the pixel circuit 130 for the global shutter operation. The capacitor CT may include a first electrode 210 and a second electrode 220 that are opposite to each other while interposing a dielectric layer 230. The first electrode 210 or the second electrode 220 may include a planar portion that extends in a plan view and a plurality of extension portions that extend from the planar portion in a vertical direction. The plurality of extension portions of the first electrode 210 and the plurality of extension portions of the second electrode 220 may be alternately disposed. Accordingly, an area of the first electrode 210 and the second electrode 220 may increase and capacitance may be enhanced. However, example embodiments are not limited thereto. A position, a shape, or the like of the capacitor CT may be variously modified.

The additional wiring portion 200 may include a semiconductor substrate, and a logic circuit portion, a power supply portion, or the like that includes a transistor, a wiring, or the like. For example, the first additional wiring portion 200a may include a substrate 210a, a transistor, a wiring 270a, or the like, and the second additional wiring portion 200b may include a substrate 210b, a transistor 240b, a wiring 270b, or the like. The transistor 240b that is included in the additional wiring portion 200 may have a structure different from structures of the plurality of transistors 140 that are included in the photoelectric conversion substrate 100. For example, the transistor 240b that is included in the additional wiring portion 200 may include a gate insulation layer 240i, a gate electrode 240g, spacers 240s at both sides of the gate electrode 240g, or the like on the substrate 210a or 210b. That is, each of the plurality of transistors 140 that are included in the photoelectric conversion substrate 100 may have the buried structure, and the transistor 240b that is included in the additional wiring portion 200 may have a protruded structure. However, example embodiments are not limited thereto. The transistor 240b that is included in the additional wiring portion 200 may have a buried structure.

According to some example embodiments, the plurality of transistors 140 that are included in the photoelectric conversion substrate 100 may have the buried structure and accordingly the plurality of transistors 140 that performs various roles may be easily implemented. For example, when a large number of transistors and/or various circuit elements such as the memory device or the like are included for a specific operation (e.g., the global shutter operation), the plurality of transistors 140 may be easily implemented.

The circuit region 300 of the image sensor 10 having the global shutter structure (e.g., the hybrid global shutter structure) may include a large number of circuit elements. For example, the circuit elements of the circuit region 300 may include the memory device (e.g., the capacitor CT) that stores a signal for the global shutter operation and an additional transistor other than the transfer transistor TX, the reset transistor RX, the first driving transistor SF1, and the first selection transistor SX1. A number of the additional transistor may vary according to a method, a type, a voltage, or the like configured to implement the global shutter operation. The circuit elements of the circuit region 300 may further the gain control transistor DCX or MCX, or the like.

Accordingly, at least one of the plurality of pixel regions PX may include the plurality of sub-pixel regions SP, each including the first transistor 142 and the second transistor 144. In some embodiment, at least one of the plurality of pixel regions PX may include at least one first transistor 142 and a plurality of second transistors 144. Thereby, a larger number of transistors may be included than in a case that one first transistor and one second transistor are included in one pixel region.

Since the transistor 140 has the buried structure, the plurality of transistors 140 that performs various roles may be easily formed by adjusting an etching depth of the transistor 140, an arrangement of the source region 144s and the drain region 144d of the transistor 140, or the like.

By forming the first or second insulation layer 142j or 144j on the gate electrode 140g in the transistor 140, the gate induced drain leakage current may be reduced. Since the connection wiring 150 that connects the transistor 140 and/or the doping region (e.g., the floating diffusion region 120f) has the buried structure, a leakage current and parasitic capacitance may be reduced, a number of the first contact vias 172 may be reduced, and the first wiring layer 174 may be freely disposed.

Thereby, performance and/or efficiency of the image sensor 10 may be enhanced.

For simple illustration, in a cross-sectional view or a perspective view, it is illustrated as an example that the first or the second gate insulation layer 142i or 144i are disposed at an entire portion of side surfaces of the gate electrode 140g and the first or second insulation layer 142j or 144j. However, example embodiments are not limited thereto. In some example embodiments, the first or second gate insulation layer 142i or 144i may be disposed on side surfaces of the gate electrode 140g, and might not be disposed on side surfaces of the first or second insulation layer 142j or 144j, or a boundary between the first or second gate insulation layer 142i or 144i and the first or second insulation layer 142j or 144j might not be seen or confirmed.

It is described as an example that the memory device includes the capacitor CT. However, example embodiments are not limited thereto, and the memory device may have any of various types. For example, the memory device may include a static random-access memory (SRAM) or the like. Other various modifications are possible.

It is described as an example that a large number of transistors 140 are included, and/or the image sensor 10 includes various circuit elements such as the memory device, or the like (e.g., the image sensor 10 performs the global shutter operation). However, example embodiments are not limited thereto. Example embodiments may be applied to the image sensor 10 that does not the memory device and/or does not perform the global shutter operation.

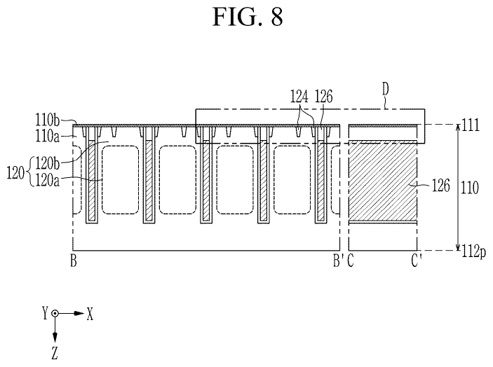

A manufacturing method of an image sensor 10 will be described in detail with reference to FIG. 8 to FIG. 16. To the extent that an element is not described in detail below, it may be understood that the element is at least substantially similar (and/or the same as) to a corresponding element that has been described elsewhere within the present disclosure. A portion which is not described in the above will be described in detail.

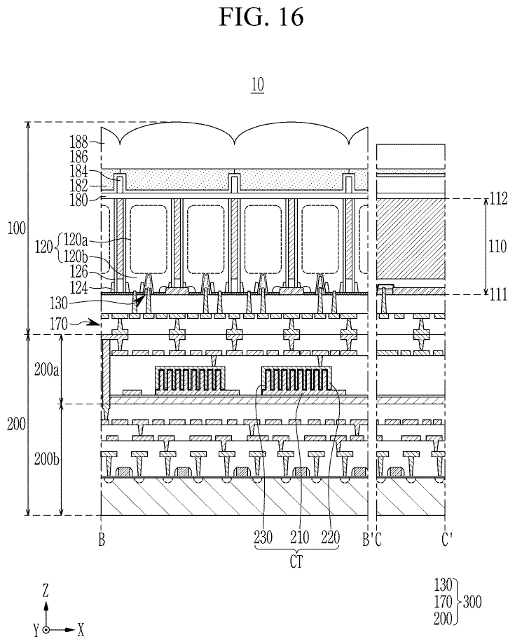

FIG. 8 to FIG. 16 are cross-sectional views that schematically illustrate a manufacturing method of an image sensor 10 according to some example embodiments. FIG. 8 and FIG. 16 illustrate a portion corresponding to FIG. 2, and FIG. 9 to FIG. 15 illustrate a portion corresponding to a portion D in FIG. 8.

As illustrated in FIG. 8, a device isolation portion 124, an isolation portion 126, and a photoelectric conversion portion 120 may be formed at a substrate 110. The substrate 110 may include a semiconductor substrate 110a and a surface insulation layer 110b, and has a first surface 111 and a preliminary surface 112p.

For example, the device isolation portion 124 and the isolation portion 126 may be formed at the semiconductor substrate 110a.

A mask pattern may be formed on a first surface of the semiconductor substrate 110a adjacent to the first surface 111 of the substrate 110. The mask pattern may have an opening that exposes a region corresponding to the device isolation portion 124. A shallow trench may be formed by etching a part of the substrate 110 that is exposed through the opening of the mask pattern. The device isolation portion 124 may be formed at a portion adjacent to the first surface of the semiconductor substrate 110a by filling an insulating material layer in the shallow trench. A mask pattern may be formed on the first surface of the semiconductor substrate 110a. The mask pattern may have an opening that exposes a region corresponding to the isolation portion 126. A deep trench may be formed by etching a part of the substrate 110 that is exposed through the opening of the mask pattern. The isolation portion 126 may be formed at a portion adjacent to the first surface of the semiconductor substrate 110a by filling an insulating material layer and/or a conductive layer in the deep trench. In some example embodiments, between the process of forming the deep trench and the process of forming the isolation portion 126, a side wall doping region may be further formed at a periphery of the isolation portion 126 by doping a dopant at the periphery of the deep trench.

In some example embodiments, the device isolation portion 124 and/or the isolation portion 126 may be formed by any of various processes, and the device isolation portion 124 and/or the isolation portion 126 may include or be formed of any of various materials.

For example, the surface insulation layer 110b may be formed on the first surface of the semiconductor substrate 110a. The surface insulation layer 110b may be formed by any of various processes (e.g., a deposition process).

For example, by doping a dopant to a partial region of the semiconductor substrate 110a in a doping process, a first conductivity type well 120a and/or a second conductivity type well 120b may be formed. The doping process may be performed by any of various processes (e.g., an ion implantation process or the like). In some example embodiments, the second conductivity type well 120b might not be formed in the doping process, or the doping process may include a process of forming a partial portion of a doping region (e.g., a floating diffusion region 120f, a ground region, or the like). Other various modifications are possible.

As illustrated in FIG. 9, a first recess R1 and a second recess R2 may be formed at the substrate 110. Further, a gate insulation layer 140i may be formed on or in the first recess R1 and the second recess R2.

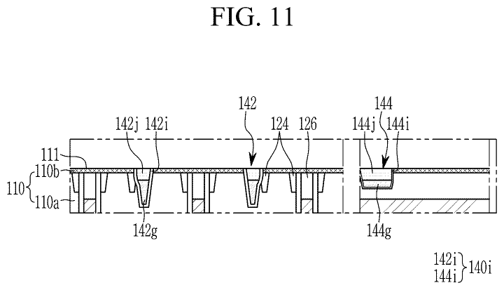

For example, the first recess R1 and the second recess R2 may be formed by performing an etching process at a side of the first surface 111 of the substrate 110. The first recess R1 may be a recess for a first transistor 142 (refer to FIG. 11). The second recess R2 may be a recess for a second transistor 144 (refer to FIG. 11). The second recess R2 may include a first recess portion R21 for a third transistor 146 (refer to FIG. 4) and a second recess portion R22 for a fourth transistor 148 (refer to FIG. 4).

For example, the first recess R1 may be formed by performing an etching process at the side of the first surface 111 of the substrate 110, and the second recess R2 may be formed by performing an etching process at the side of the first surface 111 of the substrate 110. For example, after the etching process of forming the first recess R1 is performed, the etching process of forming the second recess R2 may be performed. In some example embodiments, after the etching process of forming the second recess R2 is performed, the etching process of forming the first recess R1 may be performed.

In the etching process of forming the first recess R1, a first mask layer having a first opening may be formed on the first surface 111 of the substrate 110. In the etching process of forming the first recess R1, the first opening of the first mask layer may expose a portion of the substrate 110 where the first transistor 142 will be formed. The first recess R1 may be formed by removing a partial portion of the substrate 110 exposed by the first opening at the side of the first surface 111 of the substrate 110. After forming the first recess R1, the first mask layer may be removed.

In the etching process of forming the second recess R2, a second mask layer having a second opening may be formed on the first surface 111 of the substrate 110. In the etching process of forming the second recess R2, the second opening of the second mask layer may expose a portion of the substrate 110 where the second transistor 144 will be formed. The second recess R2 may be formed by removing a partial portion of the substrate 110 exposed by the second opening at the side of the first surface 111 of the substrate 110. After forming the second recess R2, the second mask layer may be removed.

The first or second mask layer may include or be formed of any of various materials (e.g., a photosensitive material). A patterning process of forming the first or second opening at the first or second mask layer may be performed by any of various processes (e.g., a photolithography process). The process of removing the partial portion of the substrate 110 using the first or second opening of the first or second mask layer may be performed by an etching process (e.g., a dry etching process). In the etching process, an etching material capable of etching the isolation portion 126, the device isolation portion 124, and/or the semiconductor substrate 110a may be used. The process of removing the first or second mask layer may be performed by any of various etching processes (e.g., a dry etching process and/or a wet etching process). However, example embodiments are not limited thereto. Various modifications are possible.

In some example embodiments, a channel portion of a transistor (e.g., a third transistor) may be formed by performing a doping process. However, example embodiments are not limited thereto. The doping process may be omitted.

Subsequently, a gate insulation layer 140i may be formed in the first recess R1 and the second recess R2. For example, the gate insulation layer 140i may be formed using a thermal oxidation process or the like. Accordingly, the gate insulation layer 140i may be partially formed on an exposed portion of the semiconductor substrate 110a where the surface insulation layer 110b is not disposed. In this instance, the gate insulation layer 140i may include or be formed of silicon oxide. However, example embodiments are not limited thereto. The gate insulation layer 140i may be formed by any of various processes.

The gate insulation layer 140i may include or be formed of at least one of oxide, nitride, oxynitride, a high dielectric constant material that has a dielectric constant higher than a dielectric constant of silicon oxide, or a low dielectric constant material that has a dielectric constant lower than a dielectric constant of silicon oxide, but example embodiments are not limited thereto. For example, the gate insulation layer 140i may include or be formed of at least one of silicon oxide, silicon nitride, silicon oxynitride, hafnium oxide, aluminum oxide, or tantalum oxide. The gate insulation layer 140i may include or be formed of one insulation layer, or include a plurality of insulation layers.

In some example embodiments, a first gate insulation layer 142i that has a relatively large thickness may be formed on or in the first recess R1 and a second gate insulation layer 144i has a relatively small thickness may be formed on or in the second recess R2. For example, after the first gate insulation layer 142i that has the relatively large thickness may be formed on or in the first recess R1, the first gate insulation layer 142i on or in the second recess R2 may be removed and the second gate insulation layer 144i that has the relatively small thickness may be formed on or in the second recess R2. The process of removing the first gate insulation layer 142i on or in the second recess R2 and the process of forming the second gate insulation layer 144i on or in the second recess R2 may be formed by using a mask layer that exposes the second recess R2. After forming the second gate insulation layer 144i, the mask layer may be removed.

However, example embodiments are not limited thereto. The first gate insulation layer 142i and the second gate insulation layer 144i that have different thicknesses may be formed by any of various processes.

Subsequently, as illustrated in FIG. 10, a first gate electrode 142g and a second gate electrode 144g may be formed in the first recess R1 and the second recess R2, respectively.

For example, a first buried layer may be formed on the first surface 111 of the substrate 110 to fill the first recess R1 and the second recess R2, and then, a portion of the first buried layer on the first surface 111 of the substrate 110 may be removed to form the first gate electrode 142g and the second gate electrode 144g. An etch back process may be performed at a side of the first surface 111 of the substrate 110 so that a first surface of the first gate electrode 142g and a first surface of the second gate electrode 144g are disposed inside the substrate 110.

The first buried layer may include or be formed of a conductive material or a semiconductor material that constitutes the first gate electrode 142g and the second gate electrode 144g as a base material. For example, the first buried layer may include or be formed of an undoped semiconductor material (e.g., undoped polycrystalline semiconductor, as an example, undoped polycrystalline silicon). The first buried layer may be formed by any of various processes (e.g., a deposition process).

The process of removing the partial portion of the first buried layer may be performed by any of various processes. For example, a chemical mechanical polishing process may be performed at a side of the first surface 111 of the substrate 110 to form the first gate electrode 142g and the second gate electrode 144g in the first recess R1 and the second recess R2, respectively.

In the etch back process, an etching material capable of selectively removing the first gate electrode 142g and the second gate electrode 144g may be used to remove partial portions of the first gate electrode 142g and the second gate electrode 144g.

Subsequently, as illustrated in FIG. 11, a first insulation layer 142j and a second insulation layer 144j may be formed in the first recess R1 (refer to FIG. 10) and the second recess R2 (refer to FIG. 10), respectively.

An insulation layer may be formed on the first surface 111 of the substrate 110 to fill the first recess R1 and the second recess R2, and then, a partial portion of the insulation layer on the first surface 111 of the substrate 110 may be removed.

The insulation layer may include or be formed of an insulating material that constitutes the first insulation layer 142j and the second insulation layer 144j. The insulation layer may be formed by any of various processes (e.g., a deposition process).

The process of removing the partial portion of the insulation layer may be performed by any of various processes. For example, a chemical mechanical polishing process may be performed at the side of the first surface 111 of the substrate 110 to form the first insulation layer 142j and the second insulation layer 144j in the first recess R1 and the second recess R2, respectively.

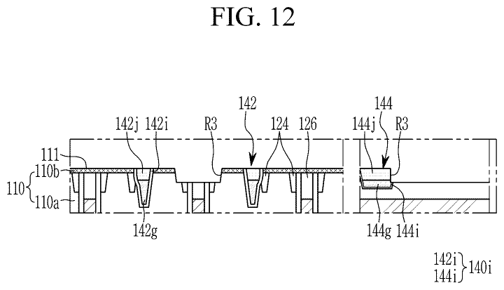

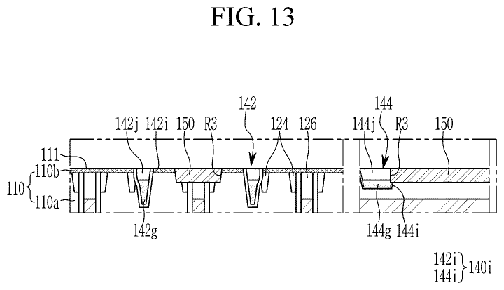

Subsequently, as illustrated in FIG. 12, a third recess R3 may be formed at the substrate 110. The third recess R3 may be a recess for a connection wiring 150 (refer to FIG. 13). For example, the third recess R3 may be formed by performing an etching process at the side of the first surface 111 of the substrate 110.

In the etching process of forming the third recess R3, a third mask layer having a third opening may be formed on the first surface 111 of the substrate 110. In the etching process of forming the third recess R3, the third opening of the third mask layer may expose a portion of the substrate 110 where the connection wiring 150 will be formed. The third recess R3 may be formed by removing a partial portion of the substrate 110 exposed by the third opening at the side of the first surface 111 of the substrate 110. After forming the third recess R3, the third mask layer may be removed.

The third mask layer may include or be formed of any of various materials (e.g., a photosensitive material). A patterning process of forming the third opening at the third mask layer may be performed by any of various processes (e.g., a photolithography process). The process of removing a partial portion of the substrate 110 using the third opening of the third mask layer may be performed by an etching process (e.g., a dry etching process). In the etching process, an etching material capable of etching the isolation portion 126, the device isolation portion 124, and/or the semiconductor substrate 110a may be used. The process of removing the third mask layer may be performed by any of various etching processes (e.g., a dry etching process and/or a wet etching process). However, example embodiments are not limited thereto. Various modifications are possible.

Subsequently, as illustrated in FIG. 13, a connection wiring 150 may be formed in the third recess R3 (refer to FIG. 12).

For example, a second buried layer may be formed on the first surface 111 of the substrate 110 to fill the third recess R3, and then, a partial portion of the second buried layer on the first surface 111 of the substrate 110 may be removed to form the connection wiring 150.

The second buried layer may include or be formed of a conductive material or a semiconductor material that constitutes the connection wiring 150 as a base material. For example, the second buried layer may include or be formed of an undoped semiconductor material (e.g., undoped polycrystalline semiconductor, as an example, undoped polycrystalline silicon). However, example embodiments are not limited thereto. the second buried layer may include or be formed of a doped semiconductor material. The second buried layer may be formed by any of various processes (e.g., a deposition process).

The process of removing the partial portion of the second buried layer may be performed by any of various processes. For example, a chemical mechanical polishing process may be performed at the side of the first surface 111 of the substrate 110 to remove the partial portion of the second buried layer.

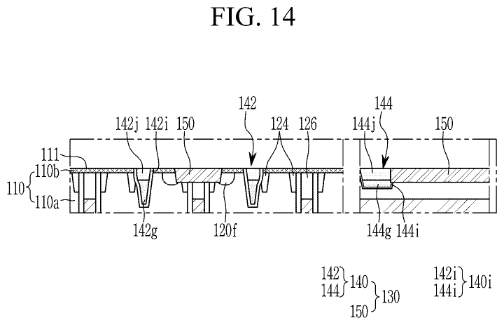

Subsequently, as illustrated in FIG. 14, a doping process may be performed to form a doping region (e.g., a floating diffusion region 120f or the like), a source region 144s (refer to FIG. 6 and FIG. 7) and a drain region 144d (refer to FIG. 6 and FIG. 7) of a transistor 140, or the like and/or to dope the connection wiring 150 with a dopant. In the doping process, the first and/or second gate electrode 142g and/or 144g may be doped, but example embodiments are not limited thereto. Accordingly, the pixel circuit 130 may be formed.

In the doping process, a corresponding portion may be exposed by using a mask layer and a dopant may be doped to the corresponding portion to have suitable conductivity type and doping concentration. An order of a doping process of the doping region (e.g., the floating diffusion region 120f, or the like), a doping process of the transistor 140, a doping process of the source region 144s and the drain region 144d, a doping process of the connection wiring 150, and/or a doping process of the first and/or second gate electrode 142g and/or 144g may be variously modified.

An opening of the mask layer may expose a portion of the substrate 110 where a doping process will be performed. A dopant may be doped to the portion of the substrate 110 exposed by the opening to have suitable conductivity type and doping concentration. After the doping process, the mask layer may be removed.

The mask layer may include or be formed of any of various materials (e.g., a photosensitive material). A patterning process of forming the opening at the mask layer may be performed by any of various processes (e.g., a photolithography process). The doping process may be performed by any of various processes (e.g., an ion implantation process or the like). The process of removing the mask layer may be performed by any of various etching processes (e.g., a dry etching process and/or a wet etching process). However, example embodiments are not limited thereto. Various modifications are possible.

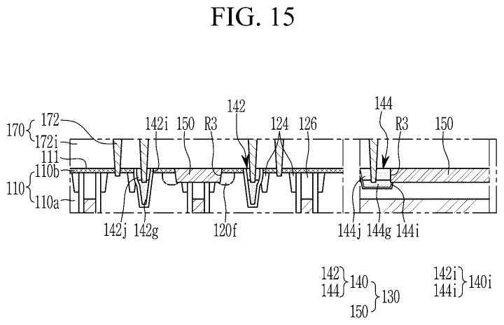

Subsequently, as illustrated in FIG. 15, a wiring portion 170 that is electrically connected to the pixel circuit 130 may be formed on the first surface 111 of the substrate 110. Any of various processes may be applied to the process of forming the wiring portion 170.

Subsequently, as illustrated in FIG. 16, a partial portion of the substrate 110 may be removed at a side of the preliminary surface 112p (refer to FIG. 8) of the substrate 110. For example, by performing a grinding process, a polishing process, an abrasive process, an etching process, or the like to the preliminary surface 112p of the semiconductor substrate 110a, the partial portion of the substrate 110 may be removed up to a portion where the isolation portion 126 is disposed. For example, the partial portion of the substrate 110 may be removed so that the isolation portion 126 passes through or penetrates a second surface 112 of the substrate 110.

An additional wiring portion 200 may be formed on the first surface 111 of the substrate 110, and a light receiving portion that includes a color filter 182, a micro lens 188, or the like may be formed on the second surface 112 of the substrate 110. For the process of forming the additional wiring portion 200 and/or the process of forming the light receiving portion, any of various processes may be applied. A manufacturing order of the process of forming the additional wiring portion 200 and the process of forming the light receiving portion may be variously modified.

According to some example embodiments, the first gate electrode 142g, the second gate electrode 144g, and the connection wiring 150 that have three or more structures having the difference in presence or absence of the gate insulation layer 140i, thickness of the gate insulation layer 140i, or presence or absence of the first or second insulation layer 142j or 144j may be formed by an easy process. Accordingly, productivity of the image sensor 10 having enhanced efficiency and performance may be enhanced.

Hereinafter, referring to FIG. 17 to FIG. 22, an image sensor according to some example embodiments will be described in detail. To the extent that an element is not described in detail below, it may be understood that the element is at least substantially similar (and/or the same as) to a corresponding element that has been described elsewhere within the present disclosure. A portion which is not described in the above will be described in detail.

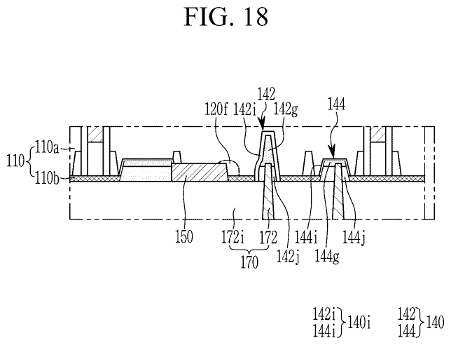

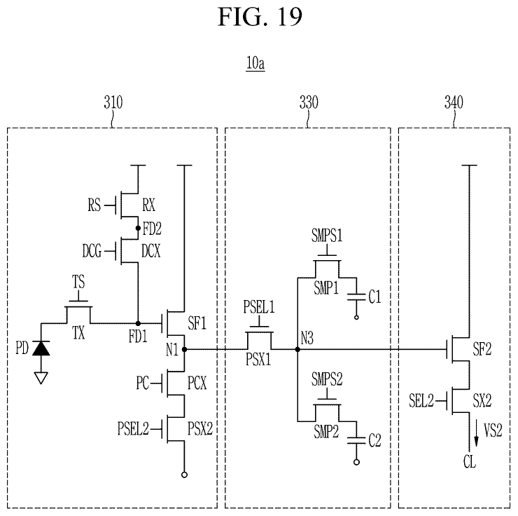

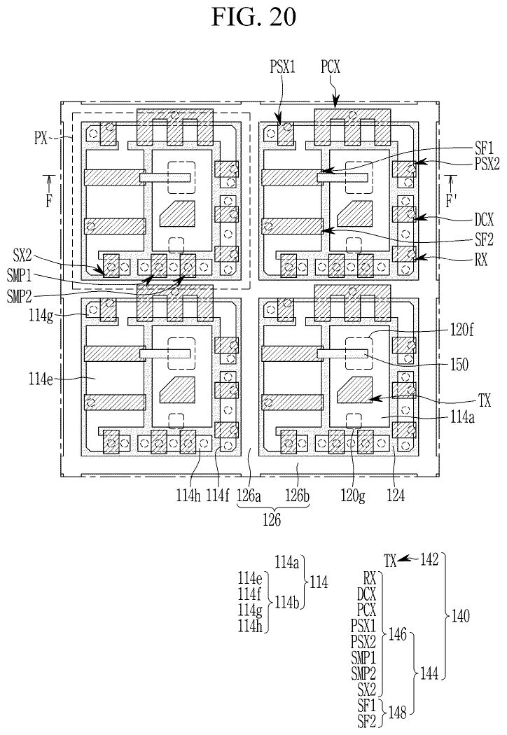

FIG. 17 is a partial cross-sectional view that illustrates an image sensor 10 according to some example embodiments. FIG. 18 is an enlarged cross-sectional view that illustrates a portion E in FIG. 17. FIG. 17 is a cross-sectional view taken along a line F-F′ in FIG. 20. FIG. 19 is a circuit diagram of a pixel array 10a that is included in the image sensor 10 illustrated in FIG. 17.

Referring to FIG. 17 to FIG. 19, in some example embodiments, an image sensor 10 may have a multi-layered stacking structure that includes a photoelectric conversion substrate 100 and an additional wiring portion 200. The additional wiring portion 200 may include or be formed of a single portion and the image sensor 10 may have a two-layered stacking structure. Accordingly, by forming a plurality of transistors 140 at a substrate 110, an additional portion (e.g., a first additional wiring portion 200a (refer to FIG. 2), a middle substrate, or a middle plate) for forming at least a part of the plurality of transistors 140 may be not need. Accordingly, a structure of the image sensor 10 may be simplified, and a number of processes and process cost may be reduced.

The image sensor 10 may have a global shutter structure that performs a global shutter operation. The image sensor 10 may include a photoelectric charge generation circuit 310, a sampling circuit 330, and a second pixel signal circuit 340.

The photoelectric charge generation circuit 310 may include a photoelectric conversion portion PD, a transfer transistor TX, a reset transistor RX, a first driving transistor SF1, and may further include a first gain control transistor DCX, a precharge transistor PCX, and a second precharge selection transistor PSX2.

Unless otherwise described, the description with reference to FIG. 1 to FIG. 7 may be applied to the photoelectric conversion portion PD, the transfer transistor TX, the reset transistor RX, the first driving transistor SF1, and/or the first gain control transistor DCX of the photoelectric charge generation circuit 310. In FIG. 19, it is illustrated as an example that a gain control transistor includes the first gain control transistor DCX and the reset transistor RX is connected between a power voltage line and a second floating diffusion node FD2. However, example embodiments are not limited thereto. as illustrated in FIG. 5, the gain control transistor may include first and second gain control transistors.

The precharge transistor PCX may precharge a first output node N1 according to a precharge control signal PC. The second precharge selection transistor PSX2 may reset the second output node N2 according to a second precharge selection control signal PSEL2.

The first precharge selection transistor PSX1 may be connected between the first output node N1 and an third output node N3. The first precharge selection transistor PSX1 may be controlled by a first precharge selection control signal PSEL1 and may reset the third output node N3. The description with reference to FIG. 1 to FIG. 7 may be applied to other portions of the sampling circuit 330 and the second pixel signal circuit 340.

In some example embodiments, a part of the plurality of transistors 140 that are included in the photoelectric charge generation circuit 310 may be included in the pixel circuit 130. For example, in some example embodiments, the plurality of transistors 140 that are included in the photoelectric charge generation circuit 310 may be included in the pixel circuit 130, and a capacitor CT of a memory device may be included in the photoelectric conversion substrate 100. The sampling transistors SMP1 and SMP2 may be included in the photoelectric conversion substrate 100. For example, the capacitor CT and sampling transistors SMP1 and SMP2 may be or correspond to an in-pixel analog memory. In some example embodiments, the additional wiring portion 200 may be or correspond to a second additional wiring portion 200b described with reference to FIG. 1 to FIG. 7. Accordingly, the description of the second additional wiring portion 200b with reference to FIG. 1 to FIG. 7 may be applied to the additional wiring portion 200 in example embodiments.

More particularly, in some example embodiments, the plurality of transistors 140 that are included in the photoelectric charge generation circuit 310, the sampling circuit 330, and the second pixel signal circuit 340 may be included in the pixel circuit 130. For example, the transfer transistor TX, the reset transistor RX, the first gain control transistor DCX, the first driving transistor SF1, the precharge transistor PCX, the first precharge selection transistor PSX1, the second precharge selection transistor PSX2, the sampling transistor SMP1 or SMP2, the second driving transistor SF2, and the second selection transistor SX2 may be included in the pixel circuit 130.

An example of the pixel circuit 130 will be described with reference to FIG. 20 together with FIG. 17 to FIG. 19.

FIG. 20 is a plan view that schematically illustrates a substrate 110 of the image sensor 10 illustrated in FIG. 17. FIG. 20 is a rear plan view that illustrates a first surface 111 of the substrate 110 that is adjacent to a wiring portion 170. For a clear understanding and simple illustration, in FIG. 20, a surface insulation layer 110b is omitted, and a pixel circuit 130 that corresponds to first to fourth pixel regions PX1, PX2, PX3, and PX4 are mainly illustrated. For a clear understanding, in FIG. 20, positions of first contact vias 172 that are electrically connected to a second gate electrode 144g, a source region 144s (refer to FIG. 21 and FIG. 22) and a drain region 144d (refer to FIG. 21 and FIG. 22) of a second transistor 144 are schematically illustrated as a dotted line.

Referring to FIG. 17 to FIG. 20, in a plan view, an isolation portion 126 may include a first isolation portion 126a that extends in a first direction (a Y-axis direction in the drawings) and a second isolation portion 126b that extends in a second direction (an X-axis direction in the drawings). The isolation portion 126 may include a portion disposed to correspond to a boundary of a plurality of pixel regions PX.

In each pixel region PX, an active region 114 may include a plurality of regions. For example, the active region 114 may include a first active region 114a where a first transistor 142 is disposed and a second active region 114b where a second transistor 144 is disposed. The second active region 114b may include a plurality of active portions 114e, 114f, 114g, and 114h. The first active region 114a, and the plurality of active portions 114e, 114f, 114g, and 114h of the second active region 114b may be separated, divided, or defined by a device isolation portion 124 (e.g., a fourth device isolation portion 124d).

In some example embodiments, the transfer transistor TX may be or correspond to the first transistor 142. The second transistor 144 may include a third transistor 146 and a fourth transistor 148. The reset transistor RX, the first gain control transistor DCX, the precharge transistor PCX, the first precharge selection transistor PSX1, the second precharge selection transistor PSX2, the sampling transistor SMP1 or SMP2, the second selection transistor SX2 may be or correspond to the third transistor 146. The first driving transistor SF1 and the second driving transistor SF2 may be or correspond to the fourth transistor 148.

For example, the first active region 114a where the first transistor 142 is disposed may be disposed in a central region of the pixel region PX, and the transfer transistor TX may be disposed in the first active region 114a. The floating diffusion region 120f and/or the ground region 120g may be disposed in the first active region 114a.

A first active portion 114e of the second active region 114b may be disposed at a first side (a left side in FIG. 20) of the pixel region PX, and the first driving transistor SF1, the second driving transistor SF2, and the second selection transistor SX2 may be disposed in the first active portion 114e of the second active region 114b.

A second active portion 114f of the second active region 114b may be disposed at a partial portion of a second side (a right side in FIG. 20) of the pixel region PX that is opposite to the first side of the pixel region PX, and the first gain control transistor DCX and the reset transistor RX may be disposed in the second active portion 114f of the second active region 114b.

A third active portion 114g of the second active region 114b may be disposed at a third side (an upper side in FIG. 20) of the pixel region PX and at the other portion of the second side (the left side in FIG. 20) of the pixel region PX. The third active portion 114g of the second active region 114b may be connected to the first active portion 114e of the second active region 114b. The first precharge selection transistor PSX1, the second precharge selection transistor PSX2, and the precharge transistor PCX may be disposed in the third active portion 114g of the second active region 114b.

A fourth active portion 114h of the second active region 114b may be disposed at a partial portion of a fourth side (a lower side in FIG. 20) of the pixel region PX that is opposite to the third side of the pixel region PX. The fourth active portion 114h of the second active region 114b may be disposed between the first active portion 114e and the second active portion 114f at the fourth side of the pixel region PX. The sampling transistor SMP1 or SMP2 may be disposed in the fourth active portion 114h of the second active region 114b.

In some example embodiments, the plurality of transistors 140 configured to operate the image sensor 10 may be disposed in one pixel region PX. In FIG. 20, it is illustrated as an example that the plurality of transistors 140 configured to operate a pixel array 10a are disposed in one pixel region PX. Accordingly, an integration degree of the pixel region PX may be enhanced. However, example embodiments are not limited thereto. In some example embodiments, the plurality of pixel regions PX may constitute one unit pixel. An arrangement of the active region 114 and an arrangement of the plurality of transistors 140 illustrated in FIG. 20 are examples, but example embodiments are not limited thereto.

In some example embodiments, the plurality of transistors 140 may have a buried structure that is buried inside the substrate 110. For example, the transfer transistor TX, the reset transistor RX, the first gain control transistor DCX, the first driving transistor SF1, the precharge transistor PCX, the first precharge selection transistor PSX1, the second precharge selection transistor PSX2, the sampling transistor SMP1 or SMP2, the second selection transistor SX2, and the second driving transistor SF2 may have the buried structure. The description with reference to FIG. 1 to FIG. 7 may be applied to the buried structure.

In some example embodiments, a connection wiring 150 may electrically connect the first driving transistor SF1 and the floating diffusion region 120f in the first active region 114a and have a buried structure that is buried inside the substrate 110. The connection wiring 150 may constitute at least a partial portion of a first floating diffusion node FD1 illustrated in FIG. 19.

In some example embodiments, the connection wiring 150 may electrically connect the floating diffusion region 120f and the first driving transistor SF1 in a plan view. That is, the connection wiring 150 may directly connect the floating diffusion region 120f to the first driving transistor SF1 without an additional wiring (e.g. without going through a wiring portion 170, more particularly, without going through a first contact via 172 and/or a first wiring layer). Accordingly, a plurality of first contact vias that are connected to a plurality of floating diffusion regions 120f, a first contact via that is electrically connected to a second gate electrode 144g of the first driving transistor SF1, and a wiring portion of the first wiring layer that connects the first contact vias may be omitted. Thereby, a leakage current and/or parasitic capacitance may be reduced and efficiency of the image sensor 10 may be enhanced. The wiring portion 170 (e.g., the first wiring layer) may be freely disposed.

In some example embodiments, the plurality of transistors 140 may have the buried structure and accordingly the plurality of transistors 140 (e.g., the plurality of second transistors 144) that perform various roles may be more easily formed. Referring to FIG. 21 and FIG. 22 together with FIG. 17 and FIG. 20, various examples of the second transistor 144 will be described in detail.

FIG. 21 is a rear perspective view that conceptually illustrates the reset transistor RX and the first gain control transistor DCX illustrated in FIG. 20. In FIG. 21, structures of the reset transistor RX and the first gain control transistor DCX are conceptually illustrated to describe electrical connection structures of the reset transistor RX and the first gain control transistor DCX.

Referring to FIG. 17, FIG. 20 and FIG. 21, a plurality of second transistors 144 according to some example embodiments may have a cascade structure. That is, a plurality of second gate electrodes 144g that are included in the plurality of second transistors 144 may be spaced apart from each other to form a row in a direction (e.g., a first direction (a Y-axis direction in the drawings)). Source/drain regions 120sd may be disposed between the plurality of second gate electrodes 144g and both outer sides of the plurality of second gate electrodes 144g. First contact vias 172 may be disposed on or electrically connected to the source/drain regions 120sd disposed between the plurality of second gate electrodes 144g and the both outer sides of the plurality of second gate electrodes 144g, respectively. Accordingly, the plurality of transistors 140 may be disposed to have a high integration degree.

For example, the second gate electrodes 144g of the reset transistor RX and the first gain control transistor DCX may be spaced apart from each other to form a row in one direction (e.g., the first direction (the Y-axis direction in the drawings)). The source/drain regions 120sd and the first contact vias 172 may be disposed at an outside of the reset transistor RX, between the reset transistor RX and the first gain control transistor DCX, and at an outside of the first gain control transistor DCX, respectively.

A plurality of second insulation layers 144j may be disposed on first surfaces of the plurality of second gate electrodes 144g, respectively, that are adjacent to a first surface of the substrate 110 to each have a buried structure. In a plan view, the plurality of second insulation layers 144j of the plurality of second transistors 144 may overlap the plurality of second gate electrodes 144g of the plurality of second transistors 144, respectively. For example, the plurality of second insulation layer 144j of the plurality of second transistors 144 may be disposed in substantially the same position as the second gate electrodes 144g of the plurality of second transistors 144 and may have substantially the same planar shapes as the second gate electrodes 144g of the plurality of second transistors 144, respectively.

In the description referring to FIG. 21, the reset transistor RX and the first gain control transistor DCX are described as an example. The description referring to FIG. 21 may be applied to another transistor.

FIG. 22 is a rear perspective view that conceptually illustrates the precharge transistor PCX illustrated in FIG. 20. In FIG. 22, a structure of the precharge transistor PCX is conceptually illustrated to describe an electrical connection structure of the precharge transistor PCX.

Referring to FIG. 17, FIG. 20, and FIG. 22, a second gate electrode 144g of the precharge transistor PCX may include a gate extension portion 144m that extends in a second direction (an X-axis direction in the drawings) and a plurality of gate branch portions 144n that extend in a first direction (an Y-axis direction) that crosses or is transverse to the first direction. The plurality of gate branch portions 144n may extend from the gate extension portion 144m. A connection doping portion 120c may be disposed between the plurality of gate branch portions 144n at a portion of the substrate 110 that is adjacent to a first surface of the substrate 110. The connection doping portion 120c may include at least a partial portion of a channel portion of the precharge transistor PCX. Accordingly, carriers may move illustrated in a dotted line arrow in FIG. 22. Accordingly, a gate length may be relatively increased. Accordingly, deterioration of the precharge transistor PCX due to differences caused by a process error may be limited or prevented and/or properties of the precharge transistor PCX may be enhanced.

In the drawings, it is illustrated as an example that the gate extension portion 144m extends in the second direction (the X-axis direction in the drawings) and the gate branch portion 144n extends the first direction (the Y-axis direction in the drawings), but example embodiments are not limited thereto. In some example embodiments, the gate extension portion 144m may extend in the first direction, and the gate branch portion 144n may extend in the second direction. In some example embodiments, the gate extension portion 144m and the gate branch portion 144n may be formed in a direction that is different from the first direction and/or the second direction.

A plurality of second insulation layer 144j may be disposed on a first surfaces of the second gate electrode 144g of the precharge transistor PCX that is adjacent to a first surface of the substrate 110 to have a buried structure. In a plan view, the second insulation layer 144j of the precharge transistor PCX may overlap the second gate electrode 144g of the precharge transistor PCX. For example, the second insulation layer 144j of the precharge transistor PCX may be disposed in substantially the same position as the second gate electrode 144g of the precharge transistor PCX and may have substantially the same planar shape as the second gate electrode 144g of the precharge transistor PCX. For example, the second insulation layer 144j of the precharge transistor PCX may include an insulation extension portion 144u on the gate extension portion 144m and a plurality of insulation branch portion 144v respectively on the plurality of gate branch portions 144n.

In some example embodiments, one of a source region 144s and a drain region 144d may be disposed at a first outer side of the plurality of gate branch portions 144n in an extension direction of the gate extension portion 144m, and the other one of the source region 144s and the drain region 144d may be disposed at a second outer side of the plurality of gate branch portions 144n that is opposite to the first outer side in the extension direction of the gate extension portion 144m. The first contact vias 172 that are electrically connected to the precharge transistor PCX may include a gate contact via 172g that is electrically connected to the second gate electrode 144g (more particularly, the gate extension portion 144m), a source contact via 172s that is electrically connected to the source region 144s, and a drain contact via 172d that is electrically connected to the drain region 144d.

In FIG. 17 to FIG. 19, it is illustrated as an example that the image sensor 10 may have the global shutter structure that performs the global shutter operation. However, example embodiments are not limited thereto. In some example embodiments, the image sensor 10 may have a hybrid global shutter structure the global shutter operation and a rolling shutter operation. Other various modifications are possible.

While some inventive concepts have been described in connection with what are presently considered to be some example embodiments, it is to be understood that inventive concepts are not limited to the described example embodiments, and that the inventive concepts are intended to cover various modifications and equivalent arrangements included within the spirit and scope of the appended claims.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

The notion that elements are “substantially the same” may indicate that the element may be completely the same and may also indicate that the elements may be determined to be the same in consideration of errors or deviations occurring during a process.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

What is claimed is:

1. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate,
wherein the pixel circuit includes a plurality of transistors,
wherein the plurality of transistors includes a first transistor and a second transistor, the first transistor including a first gate electrode and the second transistor including a second gate electrode,
wherein the second gate electrode has a structure, a shape, or a depth that is different from a structure, a shape, or a depth of the first gate electrode, and
wherein the plurality of transistors has a buried structure wherein at least one of first gate electrode or the second gate electrode is at least partially buried inside the substrate.

2. The image sensor of claim 1, further comprising:
a memory device that is electrically connected to the pixel circuit.

3. The image sensor of claim 1, wherein the first transistor further includes a first insulation layer, the first insulation layer being on a first surface of the first gate electrode and having a buried structure at least partially buried inside the substrate, the first surface of the gate electrode being at a side of the first surface of the substrate; or
Wherein the second transistor further includes a second insulation layer, the second insulation layer being on a first surface of the second gate electrode and having a buried structure at least partially buried inside the substrate, the first of the second gate electrode being at the side of the first surface of the substrate; or
wherein the first surface of the first gate electrode is at least partially inside the substrate; or
wherein the first surface of the second gate electrode is at least partially inside the substrate.

4. The image sensor of claim 2, wherein the first transistor includes a transfer transistor,
wherein the second transistor includes at least one of a reset transistor, a gain control transistor, a driving transistor, a selection transistor, a precharge transistor, a precharge selection transistor, or a sampling transistor, and
wherein the memory device includes a capacitor.

5. The image sensor of claim 1, wherein the second transistor includes a driving transistor, and
wherein a connection wiring has a buried structure at least partially buried inside the substrate and electrically connects the driving transistor to a floating diffusion region that is in the substrate.

6. The image sensor of claim 5, wherein the connection wiring connects the floating diffusion region to the driving transistor in plan view, or the connection wiring directly connects the floating diffusion region to the driving transistor.

7. The image sensor of claim 5, wherein the plurality of pixel regions includes a first pixel region and a second pixel region that are adjacent to each other,
wherein the connection wiring includes a first connection wiring, a second connection wiring, and a third connection wiring,
wherein the first connection wiring is electrically connected to a first floating diffusion region in the first pixel region,
wherein the second connection wiring is electrically connected to a second floating diffusion region in the second pixel region, and
wherein the third connection wiring electrically connects the first connection wiring and the second connection wiring to the driving transistor.

8. The image sensor of claim 4, wherein a first surface of the first gate electrode or a first surface of the second gate electrode is at a side of the first surface of the substrate and at least partially inside the substrate,
wherein a first surface of a connection wiring is at the side of the first surface of the substrate, and
wherein a distance between the first surface of the first gate electrode and the first surface of the substrate or a distance between the first surface of the second gate electrode and the first surface of the substrate is greater than a distance between the first surface of the connection wiring and the first surface of the substrate.

9. The image sensor of claim 2, comprising:
a photoelectric conversion substrate that includes the photoelectric conversion portion, the substrate, the pixel circuit, and a wiring portion electrically connected to the pixel circuit; and
an additional wiring portion that is on the photoelectric conversion substrate,
wherein the memory device is included in the additional wiring portion, or the memory device is included in the wiring portion.

10. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate,
wherein the pixel circuit includes a plurality of transistors,
wherein the plurality of transistors includes a first transistor and a second transistor, the first transistor including a first gate electrode and the second transistor including a second gate electrode,
wherein the first gate electrode is a vertical transfer gate electrode,
wherein the second gate electrode has a structure, a shape, or a depth different from a structure, a shape, or a depth of the first gate electrode,
wherein at least one of the plurality of pixel regions includes a plurality of sub-pixel regions, each of the pixel regions includes the first transistor and the second transistor, or at least one of the plurality of pixel regions includes at least one first transistor and a plurality of second transistors, and
wherein the plurality of transistors has a buried structure in which at least one of the first gate electrode or the second gate electrode is at least partially inside the substrate.

11. The image sensor of claim 10, wherein the first transistor further includes a first insulation layer, the first insulation layer being on a first surface of the first gate electrode and having a buried structure at least partially buried inside the substrate, the first surface of the first gate electrode being at a side of the first surface of the substrate; or
Wherein the second transistor further includes a second insulation layer, the second insulation layer being on a first surface of the second gate electrode and having a buried structure at least partially buried inside the substrate, the first surface of the second gate electrode being at the side of the first surface of the substrate.

12. The image sensor of claim 10, wherein a first surface of the first gate electrode at a side of the first surface of the substrate is at least partially inside the substrate; or
wherein a first surface of the second gate electrode at the side of the first surface of the substrate is at least partially inside the substrate.

13. The image sensor of claim 10, wherein the second transistor includes a driving transistor, and
wherein a connection wiring has a buried structure at least partially buried inside the substrate and electrically connects the driving transistor to a floating diffusion region that is in the substrate.

14. The image sensor of claim 13, wherein the connection wiring connects the floating diffusion region to the driving transistor in a plan view, or the connection wiring directly connects the floating diffusion region to the driving transistor.

15. The image sensor of claim 10, wherein the plurality of pixel regions includes a first pixel region and a second pixel region that are adjacent to each other,
wherein the second gate electrode that is included in the second transistor includes a first gate portion in the first pixel region, a second gate portion in the second pixel region, and a third gate portion that connects the first gate portion to the second gate portion,
wherein one of a source region and a drain region is between the first gate portion and the second gate portion, and
wherein the other one of the source region and the drain region is at an outer side of the first gate portion and at an outer side of the second gate portion.

16. The image sensor of claim 10, wherein the second transistor includes a plurality of second transistors,
wherein a plurality of second gate electrodes that are included in the plurality of second transistors are spaced apart from each other in one direction in the form of a row, and
wherein contact vias are between the plurality of second transistors and at both outer sides of the plurality of second transistors.

17. The image sensor of claim 10, wherein the second gate electrode that is included in the second transistor includes a gate extension portion and a plurality of gate branch portions that extend from the gate extension portion, the gate extension portion extending in one direction and the plurality of gate branch portions extending in a crossing direction, the crossing direction crossing or transverse to the one direction,
wherein a connection doping portion is between the plurality of gate branch portions at a portion of the substrate that is adjacent to the first surface of the substrate, and
wherein a source region is at a first outer side of the plurality of gate branch portions, and a drain region is at a second outer side of the plurality of gate branch portions that is opposite to the first outer side.

18. An image sensor, comprising:
a substrate including a first surface and a second surface opposite each other; and
a plurality of pixel regions, at least one of the plurality of pixel regions including a photoelectric conversion portion in the substrate and a pixel circuit adjacent to the first surface of the substrate,
wherein the pixel circuit includes a transistor, the transistor including a gate electrode and an insulation layer,
wherein the gate electrode has a buried structure that is at least partially buried inside the substrate, and
wherein the insulation layer is on a first surface of the gate electrode, at a side of the first surface of the substrate, and has a buried structure in which at least a partial portion of the insulation layer is buried inside the substrate.

19. The image sensor of claim 18, further comprising:
a connection wiring that is electrically connected to the transistor and has a buried structure at least partially buried inside the substrate,
wherein a first surface of a connection wiring is at the side of the first surface of the substrate, and
wherein a distance between the first surface of the gate electrode and the first surface of the substrate is greater than a distance between the first surface of the connection wiring and the first surface of the substrate,
wherein the first surface of the gate electrode is at least partially inside the substrate and a first surface of the connection wiring at the side of the first surface of the substrate is not inside the substrate.

20. The image sensor of claim 19, wherein the connection wiring has a depth that is less than a depth of the transistor, or
wherein the connection wiring has a depth greater than a thickness of the insulation layer.
